(19) United States
(12) Patent Application Publication
(10) Pub. No.: US 2025/0386646 A1
(43) Pub. Date: Dec. 18, 2025

(54) DISPLAY DEVICE AND ELECTRONIC DEVICE INCLUDING THE SAME

(71) Applicant: Samsung Display Co., LTD., Yongin-si (KR)

(72) Inventors: Tae Young SONG, Yongin-si (KR); Young Soo KWON, Yongin-si (KR); Soo Dong KIM, Yongin-si (KR); Won Gap YOON, Yongin-si (KR); Ki Heon LEE, Yongin-si (KR)

(73) Assignee: Samsung Display Co., LTD., Yongin-si (KR)

(21) Appl. No.: 19/029,444

(22) Filed: Jan. 17, 2025

(30) Foreign Application Priority Data
Jun. 18, 2024 (KR) 10-2024-0078976
Aug. 19, 2024 (KR) 10-2024-0110226

(51) Int. Cl. H10H 29/851; H10H 29/14; H10H 29/80; H10H 29/85

(52) U.S. Cl. CPC H10H 29/8512; H10H 29/142; H10H 29/8517; H10H 29/882

(57) ABSTRACT

A display device includes a light emitting element layer including first light emitting elements, second light emitting elements, and third light emitting elements, a partition wall member disposed on the light emitting element layer, and including first receiving openings, second receiving openings, and third receiving openings, first color conversion layers disposed in the first receiving openings, second color conversion layers disposed in the second receiving openings, scattering layers disposed in the third receiving openings, a cover layer, and the scattering layers, and a color filter layer including a first color filter layer including a first color filter material, a second color filter layer including a second color filter material, and a third color filter layer including a third color filter material. The partition wall member includes a first partition wall member including the first color filter material, and a second partition wall member including the second color filter material.

### CROSS-REFERENCE TO RELATED APPLICATIONS

This application claims priority to and benefits of Korean Patent Application No. 10-2024-0078976, filed on Jun. 18, 2024, and No. 10-2024-0110226, filed on Aug. 19, 2024 in the Korean Intellectual Property Office under 35 U.S.C. § 119, the entire contents of which are incorporated herein by reference.

### BACKGROUND

### 1. Technical Field

The disclosure relates to a display device and an electronic device including the display device.

### 2. Description of the Related Art

A display device may include light emitting elements capable of emitting light independently. The light emitting elements may be combined and display an image.

Recently, research has been conducted on display devices including a color conversion layer that converts light of a color emitted from the light emitting elements into light of different colors.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display device with improved a degree of design freedom and light efficiency.

However, embodiments of the disclosure are not limited to those set forth herein. The above and other embodiments will become more apparent to one of ordinary skill in the art to which the disclosure pertains by referencing the detailed description of the disclosure given below.

According to embodiments of the disclosure, a display device includes a light emitting element layer including first light emitting elements, second light emitting elements, and third light emitting elements, a partition wall member disposed on the light emitting element layer, and including first receiving openings overlapping the first light emitting elements in a plan view, second receiving openings overlapping the second light emitting elements in a plan view, and third receiving openings overlapping the third light emitting elements in a plan view, first color conversion layers disposed in the first receiving openings, second color conversion layers disposed in the second receiving openings, scattering layers disposed in the third receiving openings, a cover layer covering the partition wall member, the first color conversion layers, the second color conversion layers, and the scattering layers, and a color filter layer disposed on the cover layer, and including a first color filter layer including a first color filter material, a second color filter layer including a second color filter material, and a third color filter layer including a third color filter material. The partition wall member includes a first partition wall member including the first color filter material, and a second partition wall member including the second color filter material.

In an embodiment, in a cross-section, the first partition wall member and the second partition wall member may be disposed between a first receiving opening of the first receiving openings and a second receiving opening of the second receiving openings adjacent to each other.

In an embodiment, in a cross-section, the first partition wall member and the second partition wall member may be disposed between adjacent ones of the first receiving openings.

In an embodiment, in a cross-section, the first partition wall member and the second partition wall member may be disposed between a first receiving opening of the first receiving openings and a third receiving opening of the third receiving openings adjacent to each other.

In an embodiment, in a cross-section, at least the first partition wall member may be disposed between a second receiving opening of the second receiving openings and a third receiving opening of the third receiving openings adjacent to each other.

In an embodiment, in a cross-section, at least the first partition wall member may be disposed between adjacent ones of the second receiving openings.

In an embodiment, in a cross-section, at least the first partition wall member may be disposed between adjacent ones of the third receiving openings.

In an embodiment, the color filter layer may define a light blocking member having a triple-layer structure in which the first color filter layer, the second color filter layer, and the third color filter layer are stacked each other.

In an embodiment, in a cross-section, a width of the light blocking member may be less than a width of the partition wall member.

In an embodiment, each of the first color conversion layers may include first color conversion particles, each of the second color conversion layers may include second color conversion particles, and each of the scattering layers may include scattering particles.

In an embodiment, each of the first partition wall member and the second partition wall member may further include a liquid repellent material.

In an embodiment, the first color filter material may selectively transmit light of red color, the second color filter material may selectively transmit light of green color, and the third color filter material may selectively transmit light of blue color.

According to embodiments of the disclosure, a display device includes a color conversion substrate, a display substrate facing the color conversion substrate, and including a plurality of light emitting elements, and a filling layer disposed between the color conversion substrate and the display substrate. The color conversion substrate includes a color filter layer including a first color filter layer including a first color filter material, a second color filter layer including a second color filter material, and a third color filter layer including a third color filter material, a partition wall member disposed on the color filter layer, and including first receiving openings overlapping the first color filter layer in a plan view, second receiving openings overlapping the second color filter layer in a plan view, and third receiving openings overlapping the third color filter layer in a plan view, first color conversion layers disposed in the first receiving openings, second color conversion layers disposed in the second receiving openings, and scattering layers disposed in the third receiving openings, and the partition wall member includes a first partition wall member including the first color filter material, and a second partition wall member including the second color filter material.

In an embodiment, the partition wall member may be directly disposed on the color filter layer.

In an embodiment, the first receiving openings may not overlap the second color filter layer and the third color filter layer in a plan view, the second receiving openings may not overlap the first color filter layer and the third color filter layer in a plan view, and the third receiving openings may not overlap the first color filter layer and the second color filter layer in a plan view.

In an embodiment, the color filter layer may define a light blocking member having a triple-layer structure in which the first color filter layer, the second color filter layer, and the third color filter layer are stacked each other.

In an embodiment, in a cross-section, a width of the light blocking member may be less than a width of the partition wall member.

In an embodiment, each of the first color conversion layers may include first color conversion particles, each of the second color conversion layers may include second color conversion particles, and each of the scattering layers may include scattering particles.

In an embodiment, each of the first partition wall member and the second partition wall member may further include a liquid repellent material.

In an embodiment, the first color filter material may selectively transmit light of red color, the second color filter material may selectively transmit light of green color, and the third color filter material may selectively transmit light of blue color.

According to an embodiment of the disclosure, an electronic device comprising a display device; and a power supply which provides power to the display device. The display device includes a light emitting element layer including first light emitting elements, second light emitting elements, and third light emitting elements; a partition wall member disposed on the light emitting element layer, and including first receiving openings overlapping the first light emitting elements in a plan view, second receiving openings overlapping the second light emitting elements in a plan view, and third receiving openings overlapping the third light emitting elements in a plan view; first color conversion layers disposed in the first receiving openings; second color conversion layers disposed in the second receiving openings; scattering layers disposed in the third receiving openings; a cover layer covering the partition wall member, the first color conversion layers, the second color conversion layers, and the scattering layers; and a color filter layer disposed on the cover layer, and including a first color filter layer including a first color filter material, a second color filter layer including a second color filter material, and a third color filter layer including a third color filter material. The partition wall member includes a first partition wall member including the first color filter material, and a second partition wall member including the second color filter material.

In an embodiment, in a cross-section, the first partition wall member and the second partition wall member may be disposed between adjacent ones of the first receiving openings.

In an embodiment, in a cross-section, at least the first partition wall member may be disposed between adjacent ones of the second receiving openings.

In an embodiment, in a cross-section, at least the first partition wall member may be disposed between adjacent ones of the third receiving openings.

In an embodiment, the color filter layer may define a light blocking member having a triple-layer structure in which the first color filter layer, the second color filter layer, and the third color filter layer are stacked each other.

In an embodiment, the electronic device may be at least one of a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a tablet computer, a phablet, a personal digital assistant (PDA), a wearable device, a laptop computer, a digital camera, a camcorder, a viewfinder, a micro display, a three-dimensional (3D) display, a vehicle, a video wall with multiple displays tiled together, a theater screen, a stadium screen, a phototherapy device, and a signboard.

Since the partition wall member includes the first partition wall member including the first color filter material and the second partition wall member including the second color filter material, a degree of design freedom when forming the partition wall member may be improved, and light efficiency of the display device may be improved.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic drawing illustrating a display device according to embodiments of the disclosure;

FIG. 2 is a schematic diagram of an equivalent circuit illustrating a sub-pixel of FIG. 1;

FIG. 3 is a schematic plan view illustrating a display panel included in the display device of FIG. 1;

FIGS. 4 to 13 are schematic drawings illustrating a display device according to an embodiment of the disclosure;

FIGS. 14 to 19 are schematic drawings illustrating a display device according to an embodiment of the disclosure;

FIGS. 20 to 26 are schematic drawings illustrating an embodiment of the display device described with reference to FIGS. 4 to 13;

FIGS. 27 to 32 are schematic drawings illustrating an embodiment of the display device described with reference to FIGS. 14 to 19;

FIGS. 33 to 39 are schematic drawings illustrating an embodiment of the display device described with reference to FIGS. 4 to 13;

FIGS. 40 to 45 are schematic drawings illustrating an embodiment of the display device described with reference to FIGS. 14 to 19;

FIGS. 46 to 52 are schematic drawings illustrating an embodiment of the display device described with reference to FIGS. 4 to 13;

FIGS. 53 to 58 are schematic drawings illustrating an embodiment of the display device described with reference to FIGS. 14 to 19;

FIG. 59 is a block diagram of an electronic device according to an embodiment; and

FIG. 60 shows schematic views of various embodiments of an electronic device.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawing is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

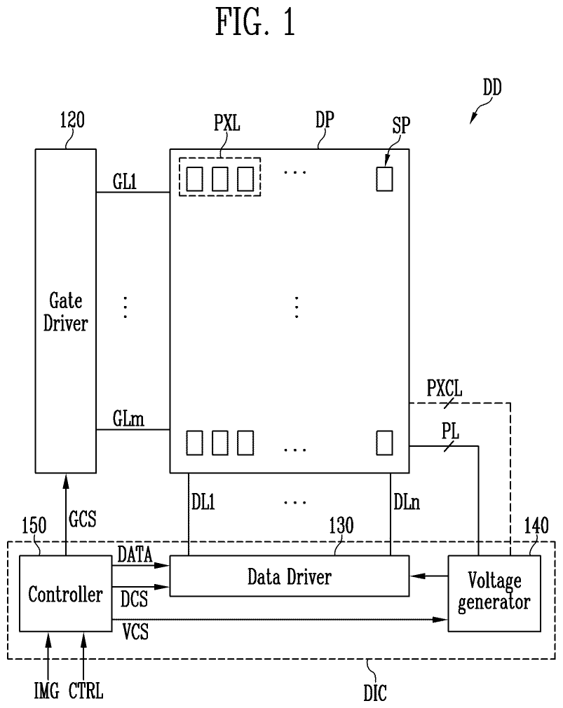

FIG. 1 is a schematic diagram illustrating a display device according to embodiments of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be electrically connected to the gate driver 120 through first to m-th gate lines GL1 to GLm. The sub-pixels SP may be electrically connected to the data driver 130 through first to n-th data lines DL1 to DLn.

The sub-pixels SP may generate light of two or more colors. For example, each of the sub-pixels SP may generate light such as red, green, blue, cyan, magenta, or yellow.

Two or more sub-pixels among the sub-pixels SP may configure (or form) a pixel PXL. For example, the pixel PXL may include three sub-pixels as shown in FIG. 1. The pixel PXL may emit light of various colors and various luminances according to a combination of light emitted from the sub-pixels included in the pixel PXL.

The gate driver 120 may be electrically connected to the sub-pixels SP disposed (e.g., arranged) in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like.

The gate driver 120 may be disposed on a side of the display panel DP. However, embodiments are not limited thereto. For example, the gate driver 120 may be divided into two or more physically and/or logically divided drivers, and such drivers may be disposed on a side of the display panel DP and another side of the display panel DP opposite the side of the display panel DP. As described above, the gate driver 120 may be adjacent to (e.g., be disposed around) the display panel DP in various shapes according to embodiments.

The data driver 130 may be electrically connected to the sub-pixels SP disposed (e.g., arranged) in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate voltages and provide the generated voltages to components of the display device DD, such as the gate driver 120, the data driver 130, and the controller 150. The voltage generator 140 may generate the voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a reference voltage (e.g., a predetermined or selectable reference voltage) may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, the pixel control lines PXCL may be electrically connected between the voltage generator 140 and the display panel DP, but embodiments are not limited thereto. For example, the pixel control lines PXCL may be electrically connected between the gate driver 120 and the display panel DP. The pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding to the input image data IMG from the outside. The controller 150 may provide the gate control signal GCS, the data control signal DCS, and the voltage control signal VCS in response to the control signal CTRL.

The controller 150 may convert the input image data IMG, and the input image data IMG may be suitable for the display device DD or the display panel DP. The controller 150 may output the image data DATA. In embodiments, the controller 150 may output the image data DATA by aligning the input image data IMG, and the input image data IMG may be suitable for the sub-pixels SP of a row.

Two or more components of the data driver 130, the voltage generator 140, and the controller 150 may be mounted on an integrated circuit. As shown in FIG. 1, the data driver 130, the voltage generator 140, and the controller 150 may be included in a driver integrated circuit DIC. The data driver 130, the voltage generator 140, and the controller 150 may be functionally divided components in a driver integrated circuit DIC. In other embodiments, at least one of the data driver 130, the voltage generator 140, and the controller 150 may be provided as (or may form) a component distinguished from the driver integrated circuit DIC.

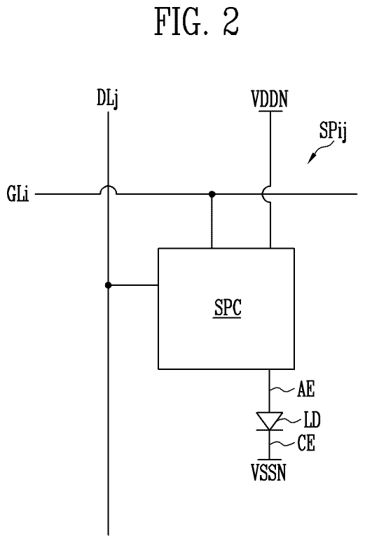

FIG. 2 is a schematic diagram of an equivalent circuit illustrating a sub-pixel of FIG. 1. In FIG. 2, among the sub-pixels SP of FIG. 1, a sub-pixel SPij disposed (e.g., arranged) in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL of FIG. 1 and receive the first power voltage. The second power voltage node VSSN may be electrically connected to another of the power lines PL of FIG. 1 and receive the second power voltage. The first power voltage may have a voltage level higher than that of the second power voltage.

The light emitting element LD may be electrically connected between an anode electrode AE and a cathode electrode CE. The anode electrode AE may be electrically connected to the first power voltage node VDDN through the sub-pixel circuit SPC. For example, the anode electrode AE may be electrically connected to the first power voltage node VDDN through one or more transistors included in the sub-pixel circuit SPC. The cathode electrode CE may be electrically connected to the second power voltage node VSSN. The light emitting element LD may emit light according to a current flowing from the anode electrode AE to the cathode electrode CE.

The sub-pixel circuit SPC may be electrically connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD and emit light according to a data signal received through the j-th data line DLj. In embodiments, the sub-pixel circuit SPC may be electrically connected to the pixel control lines PXCL of FIG. 1. The sub-pixel circuit SPC may control the light emitting element LD in response to the pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include at least one metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, and the like.

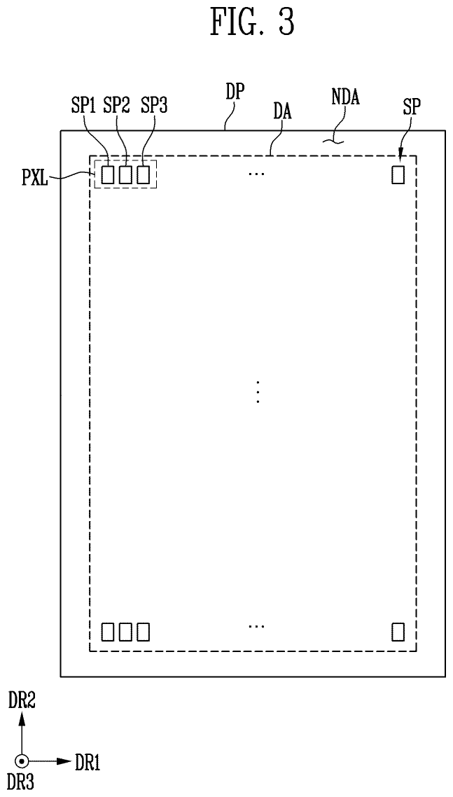

FIG. 3 is a schematic plan view illustrating the display panel included in the display device of FIG. 1.

Referring to FIG. 3, the display panel DP may include a display area DA and a non-display area NDA. The display panel DP may display an image through the display area DA. The non-display area NDA may be disposed adjacent to (e.g., disposed around) the display area DA.

The display panel DP may include the sub-pixels SP in the display area DA. The sub-pixels SP may be disposed (e.g., arranged) along a first direction DR1 and a second direction DR2 intersecting (e.g., crossing) the first direction DR1. For example, the sub-pixels SP may be disposed (e.g., arranged) in a matrix form along the first direction DR1 and the second direction DR2. As another example, the sub-pixels SP may be disposed (e.g., arranged) in a zigzag form along the first direction DR1 and the second direction DR2. However, the disclosure is not limited thereto, and an arrangement of the sub-pixels SP may vary according to embodiments. The first direction DR1 may be a column direction of the display panel DP, and the second direction DR2 may be a row direction of the display panel DP.

Two or more sub-pixels among the sub-pixels SP may configure (or form) a pixel PXL. In FIG. 3, the pixel PXL may include three sub-pixels SP1, SP2, and SP3, but embodiments are not limited thereto. For example, each pixel PXL may include two sub-pixels. Hereinafter, for convenience of description, the pixel PXL may include a first sub-pixel SP1, a second sub-pixel SP2, and a third sub-pixel SP3.

Each of the first to third sub-pixels SP1, SP2, and SP3 may generate light of various colors such as red, green, blue, cyan, magenta, and yellow. Hereinafter, for clear and concise description, the first sub-pixel SP1 may generate light of red color, the second sub-pixel SP2 may generate light of green color, and the third sub-pixel SP3 may generate light of blue color.

Each of the first to third sub-pixels SP1, SP2, and SP3 may include at least one light emitting element generating light. In embodiments, the light emitting elements of the first to third sub-pixels SP1, SP2, and SP3 may generate light of the same color. For example, the light emitting elements of the first to third sub-pixels SP1, SP2, and SP3 may generate light of blue color.

The display panel DP may include light emitting elements capable of emitting light independently. The display panel DP may include a light emitting diode display panel (LED display panel) using a micro scale or nano scale of light emitting diode as the light emitting element, an organic light emitting display panel (OLED panel) using an organic light emitting diode as the light emitting element, or the like, may be used.

Components (or elements) for controlling the sub-pixels SP may be disposed in the non-display area NDA. Lines electrically connected to the sub-pixels SP, for example, the first to m-th gate lines GL1 to GLm of FIG. 1, the first to n-th data lines DL1 to DLn, the power lines PL, and the pixel control lines PXCL, or the like may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. The data driver 130, the voltage generator 140, and the controller 150 may form (e.g., be implemented as) a driver integrated circuit DIC of FIG. 1, separate from the display panel DP, and the driver integrated circuit DIC may be electrically connected to the lines disposed in the non-display area NDA. In other embodiments, the gate driver 120, the data driver 130, the voltage generator 140, and the controller 150 may form (e.g., be implemented as) an integrated circuit.

In embodiments, the display area DA may have various shapes. The display area DA may have a closed loop shape including sides of a straight line and/or a curved line. For example, the display area DA may have shapes of a polygon, a circle, a semicircle, an ellipse, and the like.

In embodiments, the display panel DP may have a flat display surface. In other embodiments, the display panel DP may have a display surface that is at least partially round.

In embodiments, the display panel DP may be bendable, foldable, or rollable. The display panel DP and/or a substrate of the display panel DP may include materials having a flexible property.

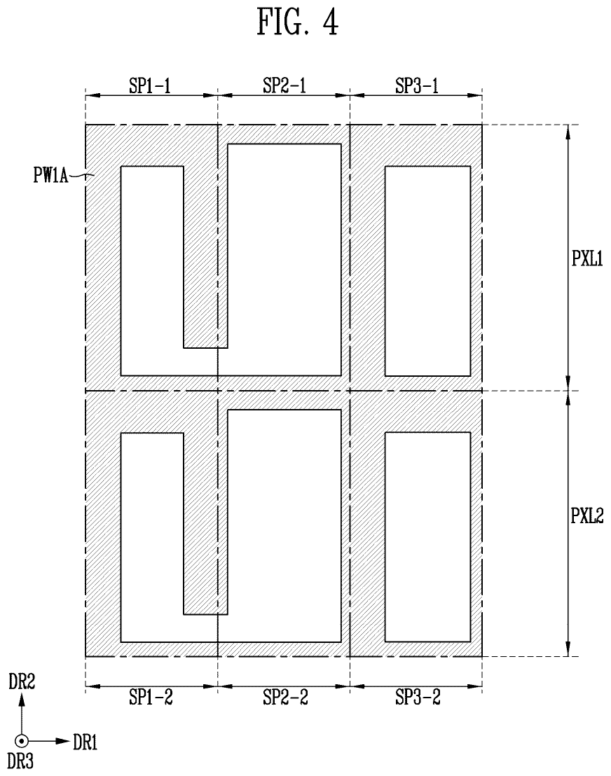

FIGS. 4 to 13 are schematic drawings illustrating a display device according to an embodiment of the disclosure.

Referring to FIGS. 4 to 9, various components (or elements) may be disposed in an area where first and second pixels PXL1 and PXL2 are provided.

The first pixel PXL1 may include a (1-1)-th sub-pixel (or a 1-1-th sub-pixel) SP1-1, a (2-1)-th sub-pixel (or a 2-1-th sub-pixel) SP2-1, and a (3-1)-th sub-pixel (or a 3-1-th sub-pixel) SP3-1.

The (1-1)-th sub-pixel SP1-1 may be a red sub-pixel emitting light of red color. The (2-1)-th sub-pixel SP2-1 may be a green sub-pixel emitting light of green color. The (3-1)-th sub-pixel SP3-1 may be a blue sub-pixel emitting light of blue color.

The (1-1)-th sub-pixel SP1-1, the (2-1)-th sub-pixel SP2-1, and the (3-1)-th sub-pixel SP3-1 may be disposed along the first direction DR1. However, embodiments are not limited thereto. For example, the (1-1)-th sub-pixel SP1-1, the (2-1)-th sub-pixel SP2-1, and the (3-1)-th sub-pixel SP3-1 may be disposed in a zigzag manner.

The second pixel PXL2 may be a pixel adjacent to the first pixel PXL1. For example, the first pixel PXL1 may be a pixel adjacent to the second pixel PXL2 in the second direction DR2.

The second pixel PXL2 may be substantially identical or similar to the first pixel PXL1. The second pixel PXL2 may include a (1-2)-th sub-pixel (or a 1-2-th sub-pixel) SP1-2, a (2-2)-th sub-pixel (or a 2-2-th sub-pixel) SP2-2, and a (3-2)-th sub-pixel (or a 3-2-th sub-pixel) SP3-2.

The (1-2)-th sub-pixel SP1-2 may be a red sub-pixel emitting light of red color. The (2-2)-th sub-pixel SP2-2 may be a green sub-pixel emitting light of green color. The (3-2)-th sub-pixel SP3-2 may be a blue sub-pixel emitting light of blue color.

The (1-2)-th sub-pixel SP1-2, the (2-2)-th sub-pixel SP2-2, and the (3-2)-th sub-pixel SP3-2 may be disposed along the first direction DR1. However, embodiments are not limited thereto. The (1-2)-th sub-pixel SP1-2, the (2-2)-th sub-pixel SP2-2, and the (3-2)-th sub-pixel SP3-2 may be disposed in a zigzag manner.

The (1-1)-th sub-pixel SP1-1 may be a sub-pixel adjacent to the (1-2)-th sub-pixel SP1-2 in the second direction DR2. The (2-1)-th sub-pixel SP2-1 may be a sub-pixel adjacent to the (2-2)-th sub-pixel SP2-2 in the second direction DR2. The (3-1)-th sub-pixel SP3-1 may be a sub-pixel adjacent to the (3-2)-th sub-pixel SP3-2 in the second direction DR2.

In FIGS. 4 to 9, for clarity and a concise description, only two pixels PXL1 and PXL2 are shown, but pixels may be provided. For example, a third pixel adjacent to the first pixel PXL1 in a direction opposite to the first direction DR1, a fourth pixel adjacent to the first pixel PXL1 in the first direction DR1, and the like may be provided. The pixels may be substantially identical or similar to each other.

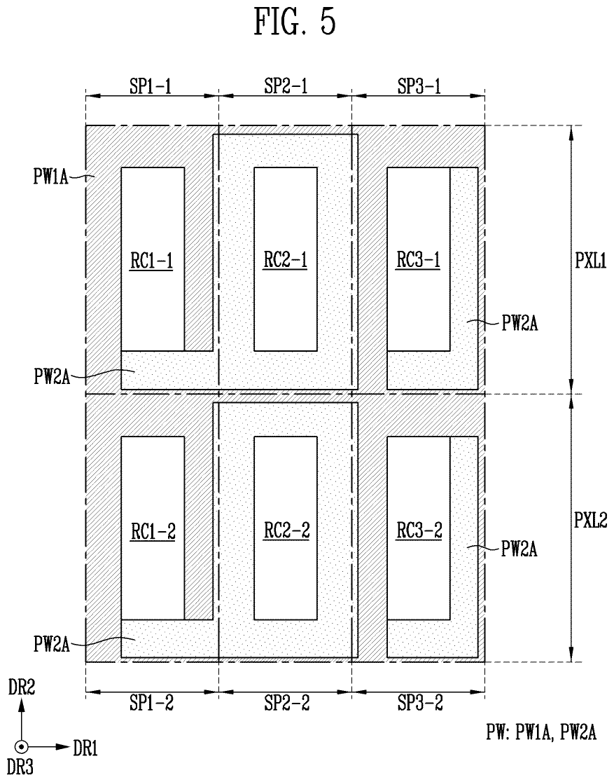

In FIGS. 4 and 5, a partition wall member (or a bank member) PW may be disposed in an area where the first and second pixels PXL1 and PXL2 are provided.

The partition wall member PW may include a (1-1)-th receiving opening (or a 1-1-th receiving opening) RC1-1 disposed in an area where the (1-1)-th sub-pixel SP1-1 is provided, a (1-2)-th receiving opening (or a 1-2-th receiving opening) RC1-2 disposed in an area where the (1-2)-th sub-pixel SP1-2 is provided, a (2-1)-th receiving opening (or a 2-1-th receiving opening) RC2-1 disposed in an area where the (2-1)-th sub-pixel SP2-1 is provided, a (2-2)-th receiving opening (or a 2-2-th receiving opening) RC2-2 disposed in an area where the (2-2)-th sub-pixel SP2-2 is provided, a (3-1)-th receiving opening (or a 3-1-th receiving opening) RC3-1 disposed in an area where the (3-1)-th sub-pixel SP3-1 is provided, and a (3-2)-th receiving opening (or a 3-2-th receiving opening) RC3-2 disposed in an area where the (3-2)-th sub-pixel SP3-2 is provided.

The (1-1)-th receiving opening RC1-1, the (1-2)-th receiving opening RC1-2, the (2-1)-th receiving opening RC2-1, the (2-2)-th receiving opening RC2-2, the (3-1)-th receiving opening RC3-1, and the (3-2)-th receiving opening RC3-2 may be spaced apart from each other.

In an embodiment, the partition wall member PW may include a first partition wall member PW1A and a second partition wall member PW2A. The (1-1)-th receiving opening RC1-1, the (1-2)-th receiving opening RC1-2, the (2-1)-th receiving opening RC2-1, the (2-2)-th receiving opening RC2-2, the (3-1)-th receiving opening RC3-1, and the (3-2)-th receiving opening RC3-2 may be defined by the first partition wall member PW1A and the second partition wall member PW2A.

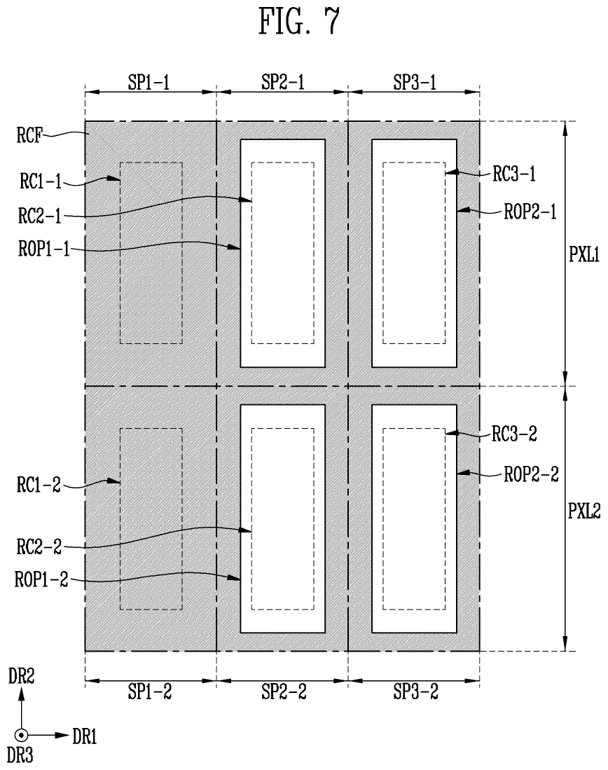

The first partition wall member PW1A may include a first color filter material included in a first color filter RCF (e.g., refer to FIG. 7). The first partition wall member PW1A and the first color filter RCF may have the same function (e.g., substantially the same or similar function). For example, the first partition wall member PW1A may selectively transmit light of red color.

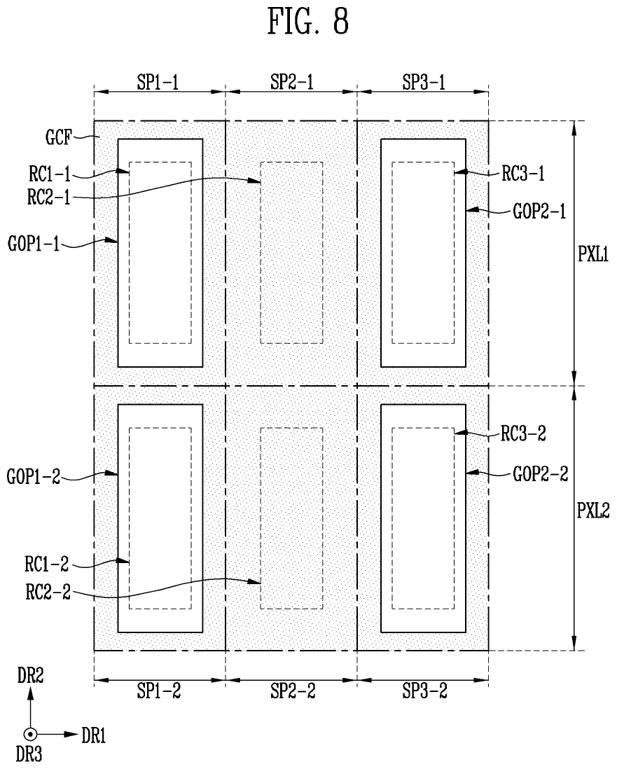

The second partition wall member PW2A may include a second color filter material included in a second color filter GCF (e.g., refer to FIG. 8). The second partition wall member PW2A and the second color filter GCF may have the same function (e.g., substantially the same or similar function). For example, the second partition wall member PW2A may selectively transmit light of green color.

In an embodiment, as shown in FIG. 5, a portion of each of the (1-1)-th receiving opening RC1-1 and the (1-2)-th receiving opening RC1-2 may be adjacent to (e.g., be surrounded by) the first partition wall member PW1A, and another portion of each of the (1-1)-th receiving opening RC1-1 and the (1-2)-th receiving opening RC1-2 may be adjacent to (e.g., be surrounded by) the second partition wall member PW2A.

In an embodiment, as shown in FIG. 5, each of the (2-1)-th receiving opening RC2-1 and the (2-2)-th receiving opening RC2-2 may be adjacent to (e.g., be surrounded by) the second partition wall member PW2A.

In an embodiment, as shown in FIG. 5, a portion of each of the (3-1)-th receiving opening RC3-1 and the (3-2)-th receiving opening RC3-2 may be adjacent to (e.g., be surrounded by) the first partition wall member PW1A, and another portion of each of the (3-1)-th receiving opening RC3-1 and the (3-2)-th receiving opening RC3-2 may be adjacent to (e.g., be surrounded by) the second partition wall member PW2A.

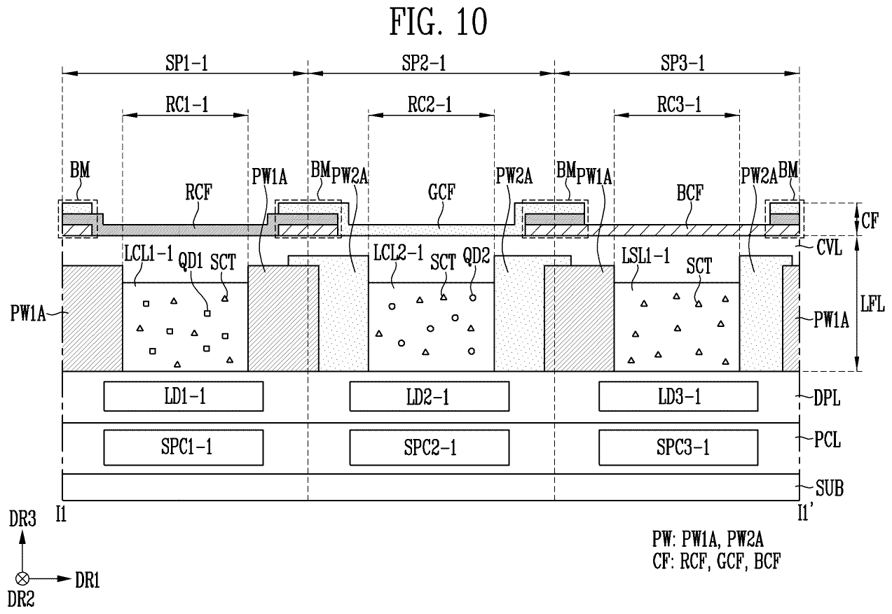

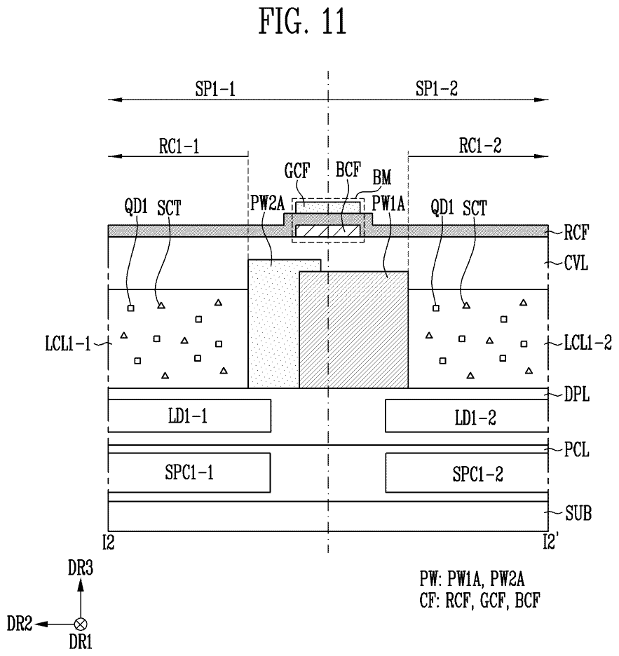

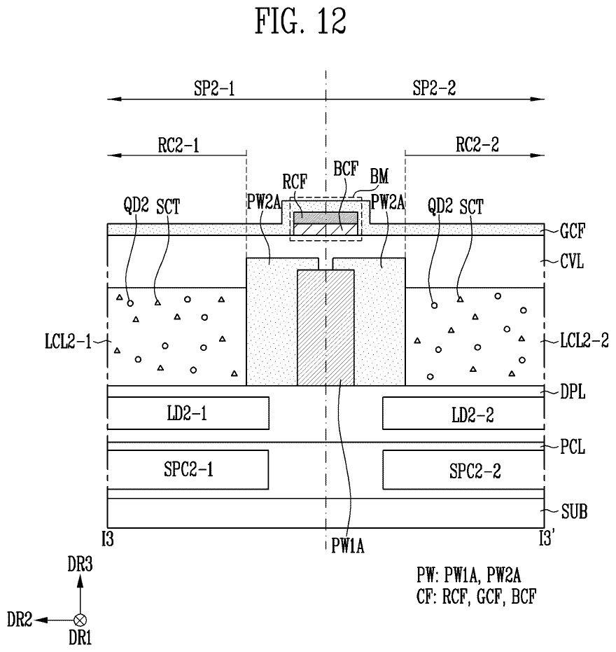

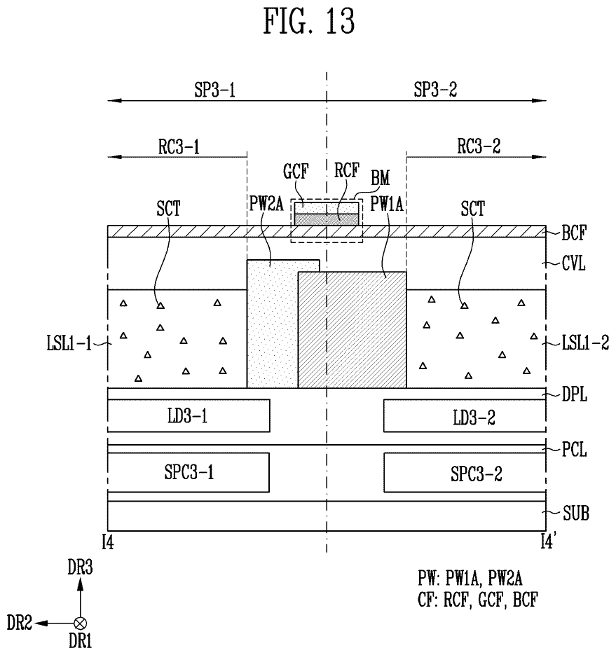

In an embodiment, each of the first and second partition wall members PW1A and PW2A may further include a liquid repellent material (e.g., a hydrophobic material). Accordingly, in an inkjet process for forming color conversion layers LCL1-1 (e.g., refer to FIG. 10), LCL1-2 (e.g., refer to FIG. 11), LCL2-1 (e.g., refer to FIG. 10), and LCL2-2 (e.g., refer to FIG. 12) and scattering layers LSL1-1 (e.g., refer to FIG. 10) and LSL1-2 (e.g., refer to FIG. 13), the color conversion layers LCL1-1, LCL1-2, LCL2-1, and LCL2-2 and the scattering layers LSL1-1 and

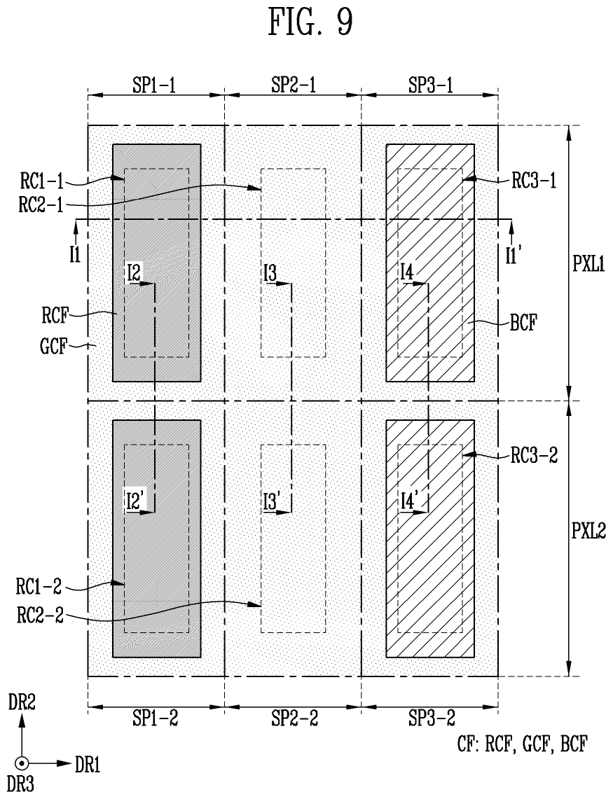

LSL1-2 may be effectively provided in the receiving openings RC1-1, RC1-2, RC2-1, RC2-2, RC3-1, and RC3-2 (e.g., refer to FIG. 9).

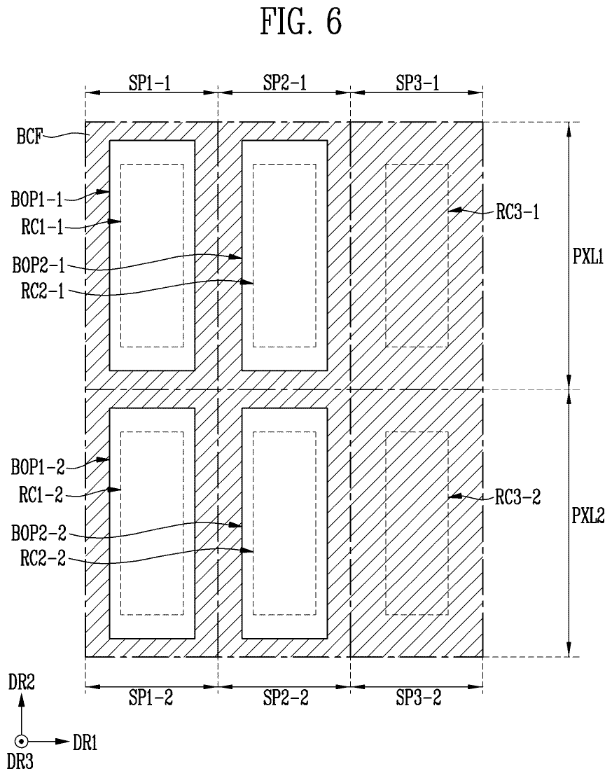

In FIGS. 6 to 9, a color filter layer CF may be disposed in an area where the first and second pixels PXL1 and PXL2 are provided.

Referring to FIG. 6 and FIG. 9, the color filter layer CF may include a third color filter layer BCF.

The third color filter layer BCF may be disposed on the partition wall member PW described with reference to FIG. 5. The third color filter layer BCF may include a third color filter material. Accordingly, the third color filter layer BCF may selectively transmit light of blue color and block light of a color different from the blue color.

In an embodiment, the third color filter layer BCF may include a (1-1)-th blue opening (or a 1-1-th blue opening) BOP1-1, a (1-2)-th blue opening (or a 1-2-th blue opening) BOP1-2, a (2-1)-th blue opening (or a 2-1-th blue opening) BOP2-1, and a (2-2)-th blue opening (or a 2-2-th blue opening) BOP2-2.

The (1-1)-th blue opening BOP1-1 may be disposed in an area where the (1-1)-th sub-pixel SP1-1 is provided. In an embodiment, the (1-1)-th blue opening BOP1-1 may have an area greater than that of the (1-1)-th receiving opening RC1-1. An edge of the (1-1)-th blue opening BOP1-1 may be adjacent to (e.g., completely surround) an edge of the (1-1)-th receiving opening RC1-1. Since the third color filter layer BCF includes the (1-1)-th blue opening BOP1-1, the light of red color emitted from the (1-1)-th sub-pixel SP1-1 may not be substantially blocked by the third color filter layer BCF. For example, the light of red color emitted from the (1-1)-th sub-pixel SP1-1 may pass through the (1-1)-th blue opening BOP1-1.

The (1-2)-th blue opening BOP1-2 may be disposed in an area where the (1-2)-th sub-pixel SP1-2 is provided. In an embodiment, the (1-2)-th blue opening BOP1-2 may have an area greater than that of the (1-2)-th receiving opening RC1-2. An edge of the (1-2)-th blue opening BOP1-2 may be adjacent to (e.g., completely surround) an edge of the (1-2)-th receiving opening RC1-2. Since the third color filter layer BCF includes the (1-2)-th blue opening BOP1-2, the light of red color emitted from the (1-2)-th sub-pixel SP1-2 may not be substantially blocked by the third color filter layer BCF. For example, the light of red color emitted from the (1-2)-th sub-pixel SP1-2 may pass through the (1-2)-th blue opening BOP1-2.

The (2-1)-th blue opening BOP2-1 may be disposed in an area where the (2-1)-th sub-pixel SP2-1 is provided. In an embodiment, the (2-1)-th blue opening BOP2-1 may have an area greater than that of the (2-1)-th receiving opening RC2-1. An edge of the (2-1)-th blue opening BOP2-1 may be adjacent to (e.g., completely surround) an edge of the (2-1)-th receiving opening RC2-1. Since the third color filter layer BCF includes the (2-1)-th blue opening BOP2-1, the light of green color emitted from the (2-1)-th sub-pixel SP2-1 may not be substantially blocked by the third color filter layer BCF. For example, the light of green color emitted from the (2-1)-th sub-pixel SP2-1 may pass through the (2-1)-th blue opening BOP2-1.

The (2-2)-th blue opening BOP2-2 may be disposed in an area where the (2-2)-th sub-pixel SP2-2 is provided. In an embodiment, the (2-2)-th blue opening BOP2-2 may have an area greater than that of the (2-2)-th receiving opening RC2-2. An edge of the (2-2)-th blue opening BOP2-2 may be adjacent to (e.g., completely surround) an edge of the (2-2)-th receiving opening RC2-2. Since the third color filter layer BCF includes the (2-2)-th blue opening BOP2-2, light of green color emitted from the (2-2)-th sub-pixel SP2-2 may not be substantially blocked by the third color filter layer BCF. For example, the light of green color emitted from the (2-2)-th sub-pixel SP2-2 may pass through the (2-2)-th blue opening BOP2-2.

Referring to FIGS. 7 and 9, the color filter layer CF may include a first color filter layer RCF.

The first color filter layer RCF may be disposed on the third color filter layer BCF (e.g., refer to FIG. 6). The first color filter layer RCF may include a first color filter material. Accordingly, the first color filter layer RCF may selectively transmit light of red color and block light of a color different from the red color.

In an embodiment, the first color filter layer RCF may include a (1-1)-th red opening (or a 1-1-th red opening) ROP1-1, a (1-2)-th red opening (or a 1-2-th red opening) ROP1-2, a (2-1)-th red opening (or a 2-1-th red opening) ROP2-1, and a (2-2)-th red opening (or a 2-2-th red opening) ROP2-2.

The (1-1)-th red opening ROP1-1 may be disposed in an area where the (2-1)-th sub-pixel SP2-1 is provided. In an embodiment, the (1-1)-th red opening ROP1-1 may have an area greater than that of the (2-1)-th receiving opening RC2-1. An edge of the (1-1)-th red opening ROP1-1 may be adjacent to (e.g., completely surround) an edge of the (2-1)-th receiving opening RC2-1. Since the first color filter layer RCF includes the (1-1)-th red opening ROP1-1, light of green color emitted from the (2-1)-th sub-pixel SP2-1 may not be substantially blocked by the first color filter layer RCF. For example, the light of green color emitted from the (2-1)-th sub-pixel SP2-1 may pass through the (1-1)-th red opening ROP1-1. In an embodiment, the (1-1)-th red opening ROP1-1 may overlap the (2-1)-th blue opening BOP2-1 (e.g., refer to FIG. 6) in a plan view.

The (1-2)-th red opening ROP1-2 may be disposed in an area where the (2-2)-th sub-pixel SP2-2 is provided. In an embodiment, the (1-2)-th red opening ROP1-2 may have an area greater than that of the (2-2)-th receiving opening RC2-2. An edge of the (1-2)-th red opening ROP1-2 may be adjacent to (e.g., completely surround) an edge of the (2-2)-th receiving opening RC2-2. Since the first color filter layer RCF includes the (1-2)-th red opening ROP1-2, light of green color emitted from the (2-2)-th sub-pixel SP2-2 may not be substantially blocked by the first color filter layer RCF. For example, the light of green color emitted from the (2-2)-th sub-pixel SP2-2 may pass through the (1-2)-th red opening ROP1-2. In an embodiment, the (1-2)-th red opening ROP1-2 may overlap the (2-2)-th blue opening BOP2-2 (e.g., refer to FIG. 6) in a plan view.

The (2-1)-th red opening ROP2-1 may be disposed in an area where the (3-1)-th sub-pixel SP3-1 is provided. In an embodiment, the (2-1)-th red opening ROP2-1 may have an area greater than that of the (3-1)-th receiving opening RC3-1. An edge of the (2-1)-th red opening ROP2-1 may be adjacent to (e.g., completely surround) an edge of the (3-1)-th receiving opening RC3-1. Since the first color filter layer RCF includes the (2-1)-th red opening ROP2-1, light of blue color emitted from the (3-1)-th sub-pixel SP3-1 may not be substantially blocked by the first color filter layer RCF. For example, the light of blue color emitted from the (3-1)-th sub-pixel SP3-1 may pass through the (2-1)-th red opening ROP2-1.

The (2-2)-th red opening ROP2-2 may be disposed in an area where the (3-2)-th sub-pixel SP3-2 is provided. In an embodiment, the (2-2)-th red opening ROP2-2 may have an area greater than that of the (3-2)-th receiving opening RC3-2. An edge of the (2-2)-th red opening ROP2-2 may be adjacent to (e.g., completely surround) an edge of the (3-2)-th receiving opening RC3-2. Since the first color filter layer RCF includes the (2-2)-th red opening ROP2-2, light of blue color emitted from the (3-2)-th sub-pixel SP3-2 may not be substantially blocked by the first color filter layer RCF. For example, the light of blue color emitted from the (3-2)-th sub-pixel SP3-2 may pass through the (2-2)-th red opening BOP2-2.

Referring to FIGS. 8 and 9, the color filter layer CF may include a second color filter layer GCF.

The second color filter layer GCF may be disposed on the first color filter layer RCF (e.g., refer to FIG. 7). The second color filter layer GCF may include a second color filter material. Accordingly, the second color filter layer GCF may selectively transmit light of green color and block light of a color different from the green color.

In an embodiment, the second color filter layer GCF may include a (1-1)-th green opening (or a 1-1-th green opening) GOP1-1, a (1-2)-th green opening (or a 1-2-th green opening) GOP1-2, a (2-1)-th green opening (or a 2-1-th green opening) GOP2-1, and a (2-2)-th green opening (or a 2-2-th green opening) GOP2-2.

The (1-1)-th green opening GOP1-1 may be disposed in an area where the (1-1)-th sub-pixel SP1-1 is provided. In an embodiment, the (1-1)-th green opening GOP1-1 may have an area greater than that of the (1-1)-th receiving opening RC1-1. An edge of the (1-1)-th green opening GOP1-1 may be adjacent to (e.g., completely surround) an edge of the (1-1)-th receiving opening RC1-1. Since the second color filter layer GCF includes the (1-1)-th green opening GOP1-1, light of red color emitted from the (1-1)-th sub-pixel SP1-1 may not be substantially blocked by the second color filter layer GCF. For example, the light of red color emitted from the (1-1)-th sub-pixel SP1-1 may pass through the (1-1)-th green opening GOP1-1. In an embodiment, the (1-1)-th green opening GOP1-1 may overlap the (1-1)-th blue opening BOP1-1 (e.g., refer to FIG. 6) in a plan view.

The (1-2)-th green opening GOP1-2 may be disposed in an area where the (1-2)-th sub-pixel SP1-2 is provided. In an embodiment, the (1-2)-th green opening GOP1-2 may have an area greater than that of the (1-2)-th receiving opening RC1-2. An edge of the (1-2)-th green opening GOP1-2 may be adjacent to (e.g., completely surround) an edge of the (1-2)-th receiving opening RC1-2. Since the second color filter layer GCF includes the (1-2)-th green opening GOP1-2, light of red color emitted from the (1-2)-th sub-pixel SP1-2 may not be substantially blocked by the second color filter layer GCF. For example, the light of red color emitted from the (1-2)-th sub-pixel SP1-2 may pass through the (1-2)-th green opening GOP1-2. In an embodiment, the (1-2)-th green opening GOP1-2 may overlap the (1-2)-th blue opening BOP1-2 (e.g., refer to FIG. 6) in a plan view.

The (2-1)-th green opening GOP2-1 may be disposed in an area where the (3-1)-th sub-pixel SP3-1 is provided. In an embodiment, the (2-1)-th green opening GOP2-1 may have an area greater than that of the (3-1)-th receiving opening RC3-1. An edge of the (2-1)-th green opening GOP2-1 may be adjacent to (e.g., completely surround) an edge of the (3-1)-th receiving opening RC3-1. Since the second color filter layer GCF includes the (2-1)-th green opening GOP2-1, light of blue color emitted from the (3-1)-th sub-pixel SP3-1 may not be substantially blocked by the second color filter layer GCF. For example, the light of blue color emitted from the (3-1)-th sub-pixel SP3-1 may pass through the (2-1)-th green opening GOP2-1. In an embodiment, the (2-1)-th green opening GOP2-1 may overlap the (2-1)-th red opening ROP2-1 (e.g., refer to FIG. 7) in a plan view.

The (2-2)-th green opening GOP2-2 may be disposed in an area where the (3-2)-th sub-pixel SP3-2 is provided. In an embodiment, the (2-2)-th green opening GOP2-2 may have an area greater than that of the (3-2)-th receiving opening RC3-2. An edge of the (2-2)-th green opening GOP2-2 may be adjacent to (e.g., completely surround) an edge of the (3-2)-th receiving opening RC3-2. Since the second color filter layer GCF includes the (2-2)-th green opening GOP2-2, light of blue color emitted from the (3-2)-th sub-pixel SP3-2 may not be substantially blocked by the second color filter layer GCF. For example, the light of blue color emitted from the (3-2)-th sub-pixel SP3-2 may pass through the (2-2)-th green opening GOP2-2. In an embodiment, the (2-2)-th green opening GOP2-2 may overlap the (2-2)-th red opening ROP2-2 (e.g., refer to FIG. 7) in a plan view.

Referring to FIGS. 6 to 9 again, a stack order of the first to third color filter layers RCF, GCF, and BCF may be variously changed. For example, in order to effectively suppress external light reflection incident from a display surface viewed by a user of the display device DD, the stack order of the first to third color filter layers RCF, GCF, and BCF may be changed, and the third color filter layer BCF may be disposed on the first and second color filter layers RCF and GCF. Thus, external light reflection incident from the display surface of the display device DD may be decreased (or prevented).

In FIG. 10, a cross-sectional view taken along line I1-I1′ of FIG. 9 is shown.

Referring to FIG. 10, the display device DD (or the display panel DP of FIG. 1) may include a substrate SUB, a pixel circuit layer PCL, a display element layer DPL, a light functional layer LFL, and a color filter layer CF.

The substrate SUB may be formed of an insulating material such as glass or resin. For example, the substrate SUB may include a glass substrate. As another example, the substrate SUB may include a polyimide (PI) substrate. In other embodiments, the substrate SUB may include a silicon wafer substrate formed using a semiconductor process.

In embodiments, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, semiconductor patterns, and conductive patterns stacked each other on the substrate SUB. The semiconductor patterns and the conductive patterns may be disposed between the insulating layers. The conductive patterns may include at least one of copper (Cu), molybdenum (MO), tungsten (W), aluminum neodymium (AlNd), titanium (Ti), aluminum (Al), and silver (Ag). However, the disclosure is not limited thereto. The conductive patterns may include an alloy of the above-described metals.

The semiconductor patterns and the conductive patterns included in the pixel circuit layer PCL may function as (or may form) transistors and capacitors of the sub-pixel circuit SPC described with reference to FIG. 2. The semiconductor patterns and the conductive patterns included in the pixel circuit layer PCL may further function as (or may form) lines, for example, the first to m-th gate lines GL1 to GLm, the first to n-th data lines DL1 to DLn, the power lines PL, and the pixel control lines PXCL of FIG. 1.

Referring to FIGS. 10 to 13, the transistors, the capacitors, and the lines included in the pixel circuit layer PCL may form the sub-pixel circuit SPC of FIG. 2 of each of the (1-1)-th sub-pixel SP1-1, the (1-2)-th sub-pixel SP1-2, the (2-1)-th sub-pixel SP2-1, the (2-2)-th sub-pixel SP2-2, the (3-1)-th sub-pixel SP3-1, and the (3-2)-th sub-pixel SP3-2. For example, FIG. 10 shows a (1-1)-th sub-pixel circuit (or a 1-1-th sub-pixel circuit) SPC1-1 of the (1-1)-th sub-pixel SP1-1, a (2-1)-th sub-pixel circuit (or a 2-1-th sub-pixel circuit) SPC2-1 of the (2-1)-th sub-pixel SP2-1, and a (3-1)-th sub-pixel circuit (or a 3-1-th sub-pixel circuit) SPC3-1 of the (3-1)-th sub-pixel SP3-1. FIG. 11 shows a (1-2)-th sub-pixel circuit (or a 1-2-th sub-pixel circuit) SPC1-2 of the (1-2)-th sub-pixel SP1-2. FIG. 12 shows a (2-2)-th sub-pixel circuit (or a 2-2-th sub-pixel circuit) SPC2-2 of the (2-2)-th sub-pixel SP2-2. FIG. 13 shows a (3-2)-th sub-pixel circuit (or a 3-2-th sub-pixel circuit) SPC3-2 of the (3-2)-th sub-pixel SP3-2.

The display element layer DPL may be disposed on the pixel circuit layer PCL. The display element layer DPL may include the light emitting element LD of FIG. 2 of each of the (1-1)-th sub-pixel SP1-1, the (1-2)-th sub-pixel SP1-2, the (2-1)-th sub-pixel SP2-1, the (2-2)-th sub-pixel SP2-2, the (3-1)-th sub-pixel SP3-1, and the (3-2)-th sub-pixel SP3-2. For example, FIG. 10 shows a (1-1)-th light emitting element (or a 1-1-th light emitting element) LD1-1 of the (1-1)-th sub-pixel SP1-1, a (2-1)-th light emitting element (or a 2-1-th light emitting element) LD2-1 of the (2-1)-th sub-pixel SP2-1, and a (3-1)-th light emitting element (or a 3-1-th light emitting element) LD3-1 of the (3-1)-th sub-pixel SP3-1. FIG. 11 shows a (1-2)-th light emitting element (or a 1-2-th light emitting element) LD1-2 of the (1-2)-th sub-pixel SP1-2. FIG. 12 shows a (2-2)-th light emitting element (or a 2-2-th light emitting element) LD2-2 of the (2-2)-th sub-pixel SP2-2. FIG. 13 shows a (3-2)-th light emitting element (or a 3-2-th light emitting element) LD3-2 of the (3-2)-th sub-pixel SP3-2.

The (1-1)-th light emitting element LD1-1 may be electrically connected to the (1-1)-th sub-pixel circuit SPC1-1. The (2-1)-th light emitting element LD2-1 may be electrically connected to the (2-1)-th sub-pixel circuit SPC2-1. The (3-1)-th light emitting element LD3-1 may be electrically connected to the (3-1)-th sub-pixel circuit SPC3-1. The (1-1)-th light emitting element LD1-1, the (2-1)-th light emitting element LD2-1, and the (3-1)-th light emitting element LD3-1 may emit light of luminance corresponding to electric signals provided from the (1-1)-th sub-pixel circuit SPC1-1, the (2-1)-th sub-pixel circuit SPC2-1, and the (3-1)-th sub-pixel circuit SPC3-1.

For example, the (1-2)-th light emitting element LD1-2 shown in FIG. 11 may be electrically connected to the (1-2)-th sub-pixel circuit SPC1-2 and may emit light of a luminance corresponding to an electric signal provided from the (1-2)-th sub-pixel circuit SPC1-2. The (2-2)-th light emitting element LD2-2 shown in FIG. 12 may be electrically connected to the (2-2)-th sub-pixel circuit SPC2-2 and may emit light of a luminance corresponding to an electric signal provided from the (2-2)-th sub-pixel circuit SPC2-2. The (3-2)-th light emitting element LD3-2 shown in FIG. 13 may be electrically connected to the (3-2)-th sub-pixel circuit SPC3-2 and may emit light of a luminance corresponding to an electric signal provided from the (3-2)-th sub-pixel circuit SPC3-2.

In an embodiment, the (1-1)-th light emitting element LD1-1, the (2-1)-th light emitting element LD2-1, the (3-1)-th light emitting element LD3-1, the (1-2)-th light emitting element LD1-2, the (2-2)-th light emitting element LD2-2, and the (3-2)-th light emitting element LD3-2 may emit light of the same color (for example, blue).

The light functional layer LFL may be disposed on the display element layer DPL. The light functional layer LFL may include a partition wall member PW, a (1-1)-th color conversion layer (or a 1-1-th color conversion layer) LCL1-1, a (2-1)-th color conversion layer (or a 2-1-th color conversion layer) LCL2-1, a (1-1)-th scattering layer (or a 1-1-th scattering layer) LSL1-1, and a cover layer CVL.

The partition wall member PW may be disposed on the display element layer DPL. In an embodiment, the partition wall member PW may be directly disposed on the display element layer DPL. For example, the partition wall member PW may be in direct contact with an upper surface of the display element layer DPL. The partition wall member PW may include a first partition wall member PW1A including a first color filter material and a second partition wall member PW2A including a second color filter material. In an embodiment, in a partial area, the second partition wall member PW2A may cover an upper surface of the first partition wall member PW1A. For example, a portion of the second partition wall member PW2A may be disposed on a portion of the first partition wall member PW1A.

The partition wall member PW may include a (1-1)-th receiving opening (or a 1-1-th receiving opening) RC1-1, a (2-1)-th receiving opening (or a 2-1-th receiving opening) RC2-1, and a (3-1)-th receiving opening (or a 3-1-th receiving opening) RC3-1 exposing the upper surface of the display element layer DPL. The (1-1)-th receiving opening RC1-1 may overlap the (1-1)-th light emitting element LD1-1 in a plan view. The (2-1)-th receiving opening RC2-1 may overlap the (2-1)-th light emitting element LD2-1 in a plan view. The (3-1)-th receiving opening RC3-1 may overlap the (3-1)-th light emitting element LD3-1 in a plan view.

The (1-1)-th color conversion layer LCL1-1 may be disposed in the (1-1)-th receiving opening RC1-1. In an embodiment, the (1-1)-th color conversion layer LCL1-1 may be disposed (e.g., directly disposed) on the display element layer DPL. For example, the (1-1)-th color conversion layer LCL1-1 may be in direct contact with the upper surface of the display element layer DPL.

The (1-1)-th color conversion layer LCL1-1 may include first color conversion particles QD1. The first color conversion particles QD1 may change a color (or wavelength) of light emitted from the (1-1)-th light emitting element LD1-1. For example, the first color conversion particles QD1 may convert the light emitted from the (1-1)-th light emitting element LD1-1 into light of red color. Accordingly, the (1-1)-th sub-pixel SP1-1 may be provided as (or may form) a red sub-pixel. In embodiments, the first color conversion particles QD1 may be quantum dots. In an embodiment, the (1-1)-th color conversion layer LCL1-1 may further include scattering particles SCT that scatter light.

The (2-1)-th color conversion layer LCL2-1 may be disposed in the (2-1)-th receiving opening RC2-1. In an embodiment, the (2-1)-th color conversion layer LCL2-1 may be disposed (e.g., directly disposed) on the display element layer DPL. For example, the (2-1)-th color conversion layer LCL2-1 may be in direct contact with the upper surface of the display element layer DPL.

The (2-1)-th color conversion layer LCL2-1 may include second color conversion particles QD2. The second color conversion particles QD2 may change a color (or wavelength) of light emitted from the (2-1)-th light emitting element LD2-1. For example, the second color conversion particles QD2 may convert the light emitted from the (2-1)-th light emitting element LD2-1 into light of green color. Accordingly, the (2-1)-th sub-pixel SP2-1 may be provided as (or may form) a green sub-pixel. In embodiments, the second color conversion particles QD2 may be quantum dots. In an embodiment, the (2-1)-th color conversion layer LCL2-1 may further include scattering particles SCT that scatters light.

The (1-1)-th scattering layer LSL1-1 may be disposed in the (3-1)-th receiving opening RC3-1. In an embodiment, the (1-1)-th scattering layer LSL1-1 may be disposed (e.g., directly disposed) on the display element layer DPL. For example, the (1-1)-th scattering layer LSL1-1 may be in direct contact with the upper surface of the display element layer DPL.

The (1-1)-th scattering layer LSL1-1 may include scattering particles SCT. The scattering particles SCT may scatter light emitted from the (3-1)-th light emitting element LD3-1 and improve light emission efficiency. Accordingly, in case that the (3-1)-th light emitting element LD3-1 emits light of blue color, the (3-1)-th sub-pixel SP3-1 may be provided as (or may form) a blue sub-pixel. In an embodiment, the scattering particles SCT may include TiO₂.

In an embodiment, the first partition wall member PW1A and the second partition wall member PW2A may be disposed (e.g., interposed) between the (1-1)-th receiving opening RC1-1 and the (2-1)-th receiving opening RC2-1 adjacent to each other. For example, as shown in FIG. 10, the first partition wall member PW1A and the second partition wall member PW2A may be disposed along the first direction DR1 between the (1-1)-th receiving opening RC1-1 and the (2-1)-th receiving opening RC2-1 adjacent to each other. The light of red color provided by the first color conversion particles QD1 included in the (1-1)-th color conversion layer LCL1-1 disposed in the (1-1)-th receiving opening RC1-1 may be blocked by the second partition wall member PW2A including the second color filter material. The light of green color provided by the second color conversion particles QD2 included in the (2-1)-th color conversion layer LCL2-1 disposed in the (2-1)-th receiving opening RC2-1 may be blocked by the first partition wall member PW1A including the first color filter material. Accordingly, light mixing between the (1-1)-th sub-pixel SP1-1 and the (2-1)-th sub-pixel SP2-1 (e.g., the adjacent (2-1)-th sub-pixel SP2-1) adjacent to each other may be prevented.

In an embodiment, the first partition wall member PW1A and the second partition wall member PW2A may be disposed (e.g., interposed) between the (2-1)-th receiving opening RC2-1 and the (3-1)-th receiving opening RC3-1 adjacent to each other. For example, as shown in FIG. 10, the second partition wall member PW2A and the first partition wall member PW1A may be disposed along the first direction DR1 between the (2-1)-th receiving opening RC2-1 and the (3-1)-th receiving opening RC3-1 adjacent to each other. The light of green color provided by the second color conversion particles QD2 included in the (2-1)-th color conversion layer LCL2-1 disposed in the (2-1)-th receiving opening RC2-1 may be blocked by the first partition wall member PW1A including the first color filter material. The light of blue color scattered by the scattering particles SCT included in the (1-1)-th scattering layer LSL1-1 disposed in the (3-1)-th receiving opening RC3-1 may be blocked by the first and second partition wall members PW1A and PW2A including the first and second color filter materials. Accordingly, light mixing between the (2-1)-th sub-pixel SP2-1 and the (3-1)-th sub-pixel SP3-1 (e.g., the adjacent (3-1)-th sub-pixel SP3-1) adjacent to each other may be prevented.

In an embodiment, a sub-pixel adjacent to the (1-1)-th sub-pixel SP1-1 in a direction opposite to the first direction DR1 may be substantially identical or similar to the (3-1)-th sub-pixel SP3-1. For example, the (3-1)-th sub-pixel SP3-1 adjacent to the (1-1)-th sub-pixel SP1-1 in the direction opposite to the first direction DR1 may further be provided. The first partition wall member PW1A and the second partition wall member PW2A may be disposed (e.g., interposed) between the (1-1)-th receiving opening RC1-1 and the (3-1)-th receiving opening RC3-1 adjacent to each other. The light of red color provided by the first color conversion particles QD1 included in the (1-1)-th color conversion layer LCL1-1 disposed in the (1-1)-th receiving opening RC1-1 may be blocked by the second partition wall member PW2A including the second color filter material. The light of blue color scattered by scattering particles SCT included in the (1-1)-th scattering layer LSL1-1 disposed in the (3-1)-th receiving opening RC3-1 may be blocked by the first and second partition wall members PW1A and PW2A including the first and second color filter materials. Accordingly, light mixing between the (1-1)-th sub-pixel SP1-1 and the (3-1)-th sub-pixel SP3-1 (e.g., the adjacent (3-1)-th sub-pixel SE3-1) adjacent to each other may be prevented.

The cover layer CVL may cover the partition wall member PW, the (1-1)-th color conversion layer LCL1-1, the (2-1)-th color conversion layer LCL2-1, and the (1-1)-th scattering layer LSL1-1. The cover layer CVL may protect components disposed under the cover layer CVL. In an embodiment, an upper surface of the cover layer CVL may be substantially flat.

The color filter layer CF may be disposed on the light functional layer LFL. The color filter layer CF may include the first color filter layer RCF including the first color filter material, the second color filter layer GCF including the second color filter material, and the third color filter layer BCF including the third color filter material.

In an embodiment, a light blocking member BM may have a triple-layer structure in which the first to third color filter layers RCF, GCF, and BCF are stacked each other. Since the light blocking member BM has a structure in which the first to third color filter layers RCF, GCF, and BCF including the first to third color filter materials are stacked each other, the light may be blocked. The light blocking member BM may be disposed between adjacent sub-pixels (e.g., adjacent ones of the sub-pixels) and prevent light mixing between adjacent sub-pixels. In an embodiment, between adjacent sub-pixels (e.g., adjacent ones of the sub-pixels) in the first direction DR1, a width of the light blocking member BM may be less than a width of the partition wall member PW in the first direction DR1.

The (1-1)-th receiving opening RC1-1 may overlap the first color filter layer RCF and may not overlap the second color filter layer GCF and the third color filter layer BCF in a plan view. Accordingly, the light of red color provided by the first color conversion particles QD1 included in the (1-1)-th color conversion layer LCL1-1 disposed in the (1-1)-th receiving opening RC1-1 may not be blocked by (or may pass through) the color filter layer CF.

The (2-1)-th receiving opening RC2-1 may overlap the second color filter layer GCF and may not overlap the first color filter layer RCF and the third color filter layer BCF in a plan view. Accordingly, the light of green color provided by the second color conversion particles QD2 included in the (2-1)-th color conversion layer LCL2-1 disposed in the (2-1)-th receiving opening RC2-1 may not be blocked by (or may pass through) the color filter layer CF.

The (3-1)-th receiving opening RC3-1 may overlap the third color filter layer BCF and may not overlap the first color filter layer RCF and the second color filter layer GCF in a plan view. Accordingly, the light of blue color scattered by the scattering particles SCT included in the (1-1)-th scattering layer LSL1-1 disposed in the (3-1)-th receiving opening RC3-1 may not be blocked by (or may pass through) the color filter layer CF.

In FIG. 11, a cross-sectional view taken along line 12-12′ of FIG. 9 is shown. Detailed description of the same or similar constituent elements (e.g., the elements of FIG. 10) is omitted.

The partition wall member PW may include the (1-2)-th receiving opening RC1-2 exposing the upper surface of the display element layer DPL. The (1-2)-th receiving opening RC1-2 may overlap the (1-2)-th light emitting element LD1-2 in a plan view. The (1-2)-th receiving opening RC1-2 may overlap the first color filter layer RCF and may not overlap the second color filter layer GCF and the third color filter layer BCF in a plan view.

The (1-2)-th color conversion layer LCL1-2 may be disposed in the (1-2)-th receiving opening RC1-2. In an embodiment, the (1-2)-th color conversion layer LCL1-2 may be disposed (e.g., directly disposed) on the display element layer DPL. For example, the (1-2)-th color conversion layer LCL1-2 may be in direct contact with the upper surface of the display element layer DPL.

The (1-2)-th color conversion layer LCL1-2 may be the same or similar to the (1-1)-th color conversion layer LCL1-1. For example, the (1-2)-th color conversion layer LCL1-2 may include the first color conversion particles QD1. Accordingly, the (1-2)-th sub-pixel SP1-2 may be provided as (or may form) a red sub-pixel. In an embodiment, the (1-2)-th color conversion layer LCL1-2 may further include scattering particles SCT.

In an embodiment, the first partition wall member PW1A and the second partition wall member PW2A may be disposed (e.g., interposed) between the (1-1)-th receiving opening RC1-1 and the (1-2)-th receiving opening RC1-2 adjacent to each other. For example, as shown in FIG. 11, the second partition wall member PW2A and the first partition wall member PW1A may be disposed along a direction opposite to the second direction DR2 between the (1-1)-th receiving opening RC1-1 and the (1-2)-th receiving opening RC1-2 adjacent to each other. Light of red color provided by the first color conversion particles QD1 included in the (1-1)-th color conversion layer LCL1-1 disposed in the (1-1)-th receiving opening RC1-1 may be blocked by the second partition wall member PW2A including the second color filter material. Light of red color provided by the first color conversion particles QD1 included in the (1-2)-th color conversion layer LCL1-2 disposed in the (1-2)-th receiving opening RC1-2 may be blocked by the second partition wall member PW2A including the second color filter material. Accordingly, light mixing between the (1-1)-th sub-pixel SP1-1 and the (1-2)-th sub-pixel SP1-2 (e.g., the adjacent (1-2)-th sub-pixel SP1-2) adjacent to each other may be prevented.

The light blocking member BM defined by the color filter layer CF may be disposed between the (1-1)-th sub-pixel SP1-1 and the (1-2)-th sub-pixel SP1-2. In an embodiment, between the (1-1)-th sub-pixel SP1-1 and the (1-2)-th sub-pixel SP1-2, a width of the light blocking member BM may be less than a width of the partition wall member PW in the second direction DR2.

In FIG. 12, a cross-sectional view taken along line 13-13′ of FIG. 9 is shown. Detailed description of the same or similar constituent elements described with reference to FIG. 10 is omitted.

The partition wall member PW may include the (2-2)-th receiving opening RC2-2 exposing the upper surface of the display element layer DPL. The (2-2)-th receiving opening RC2-2 may overlap the (2-2)-th light emitting element LD2-2 in a plan view. The (2-2)-th receiving opening RC2-2 may overlap the second color filter layer GCF and may not overlap the first color filter layer RCF and the third color filter layer BCF in a plan view.

The (2-2)-th color conversion layer LCL2-2 may be disposed in the (2-2)-th receiving opening RC2-2. In an embodiment, the (2-2)-th color conversion layer LCL2-2 may be disposed (e.g., directly disposed) on the display element layer DPL. For example, the (2-2)-th color conversion layer LCL2-2 may be in direct contact with the upper surface of the display element layer DPL.

The (2-2)-th color conversion layer LCL2-2 may be the same or similar to the (2-1)-th color conversion layer LCL2-1. For example, the (2-2)-th color conversion layer LCL2-2 may include the second color conversion particles QD2. Accordingly, the (2-2)-th sub-pixel SP2-2 may be provided as (or may form) a green sub-pixel. In an embodiment, the (2-2)-th color conversion layer LCL2-2 may further include scattering particles SCT.

In an embodiment, the first partition wall member PW1A and the second partition wall member PW2A may be disposed (e.g., interposed) between the (2-1)-th receiving opening RC2-1 and the (2-2)-th receiving opening RC2-2 adjacent to each other. For example, a second partition wall member PW2A, a first partition wall member PW1A, and another second partition wall member PW2A may be disposed in the direction opposite to the second direction DR2 between the (2-1)-th receiving opening RC2-1 and the (2-2)-th receiving opening RC2-2 adjacent to each other. Light of green color provided by the second color conversion particles QD2 included in the (2-1)-th color conversion layer LCL2-1 disposed in the (2-1)-th receiving opening RC2-1 may be blocked by the first partition wall member PW1A including the first color filter material. Light of green color provided by the second color conversion particles QD2 included in the (2-2)-th color conversion layer LCL2-2 disposed in the (2-2)-th receiving opening RC2-2 may be blocked by the first partition wall member PW1A including the first color filter material. Accordingly, light mixing between the (2-1)-th sub-pixel SP2-1 and the (2-2)-th sub-pixel SP2-2 (e.g., the adjacent (2-2)-th sub-pixel) adjacent to each other may be prevented.

The light blocking member BM defined by the color filter layer CF may be disposed between the (2-1)-th sub-pixel SP2-1 and the (2-2)-th sub-pixel SP2-2. In an embodiment, between the (2-1)-th sub-pixel SP2-1 and the (2-2)-th sub-pixel SP2-2, a width of the light blocking member BM may be less than a width of the partition wall member PW in the second direction DR2.

In FIG. 13, a cross-sectional view taken along line 14-14′ of FIG. 9 is shown. Detailed description of the same or similar constituent elements described with reference to FIG. 10 is omitted.

The partition wall member PW may include the (3-2)-th receiving opening RC3-2 exposing the upper surface of the display element layer DPL. The (3-2)-th receiving opening RC3-2 may overlap the (3-2)-th light emitting element LD3-2 in a plan view. The (3-2)-th receiving opening RC3-2 may overlap the third color filter layer BCF and may not overlap the first color filter layer RCF and the second color filter layer GCF in a plan view.

The (1-2)-th scattering layer LSL1-2 may be disposed in the (3-2)-th receiving opening RC3-2. In an embodiment, the (1-2)-th scattering layer LSL1-2 may be disposed (e.g., directly disposed) on the display element layer DPL. For example, the (1-2)-th scattering layer LSL1-2 may be in direct contact with the upper surface of the display element layer DPL.

The (1-2)-th scattering layer LSL1-2 may be the same or similar to the (1-1)-th scattering layer LSL1-1. For example, the (1-2)-th scattering layer LSL1-2 may include scattering particles SCT. Accordingly, the (3-2)-th sub-pixel SP3-2 may be provided as (or may form) a blue sub-pixel.

In an embodiment, the first partition wall member PW1A and the second partition wall member PW2A may be disposed (e.g., interposed) between the (3-1)-th receiving opening RC3-1 and the (3-2)-th receiving opening RC3-2 adjacent to each other. For example, the second partition wall member PW2A and the first partition wall member PW1A may be disposed along the direction opposite to the second direction DR2 between the (3-1)-th receiving opening RC3-1 and the (3-2)-th receiving opening RC3-2 adjacent to each other. Light of blue color scattered by the scattering particles SCT included in the (1-1)-th scattering layer LSL1-1 disposed in the (3-1)-th receiving opening RC3-1 may be blocked by the first and second partition wall members PW1A and PW2A including first and second color filter materials. Light of blue color scattered by the scattering particles SCT included in the (1-2)-th scattering layer LSL1-2 disposed in the (3-2)-th receiving opening RC3-2 may be blocked by the first and second partition wall members PW1A and PW2A including the first and second color filter materials. Accordingly, light mixing between the (3-1)-th sub-pixel SP3-1 and the (3-2)-th sub-pixel SP3-2 (e.g., the adjacent (3-2)-th sub-pixel SP3-2) adjacent to each other may be prevented.

The light blocking member BM defined by the color filter layer CF may be disposed between the (3-1)-th sub-pixel SP3-1 and the (3-2)-th sub-pixel SP3-2. In an embodiment, between the (3-1)-th sub-pixel SP3-1 and the (3-2)-th sub-pixel SP3-2, a width of the light blocking member BM may be less than a width of the partition wall member PW in the second direction DR2.

Referring to FIGS. 4 to 13 again, in the disclosure, the partition wall member PW may include the first partition wall member PW1A including the first color filter material and the second partition wall member PW2A including the second color filter material. Accordingly, in case that the partition wall member PW is formed, a degree of design freedom may be improved, and light efficiency of the display device DD may be improved.

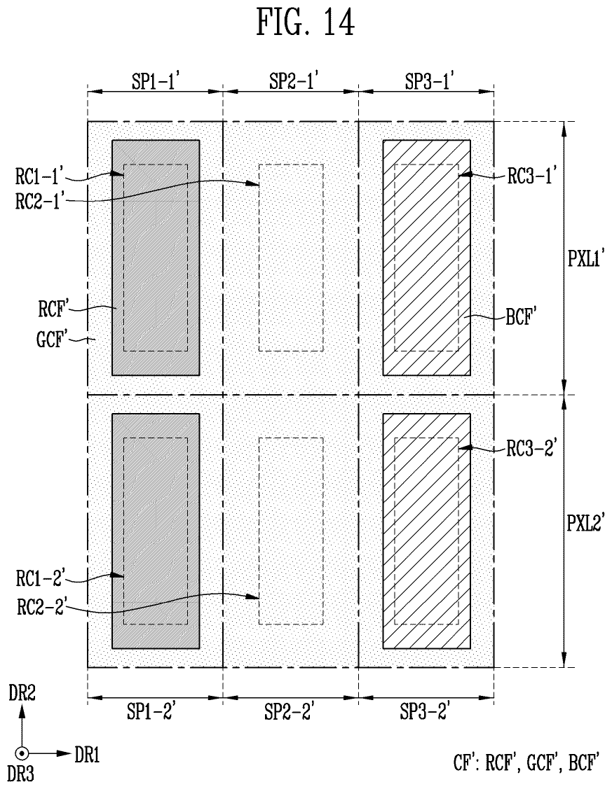

FIGS. 14 to 19 are schematic drawings illustrating a display device according to an embodiment of the disclosure.

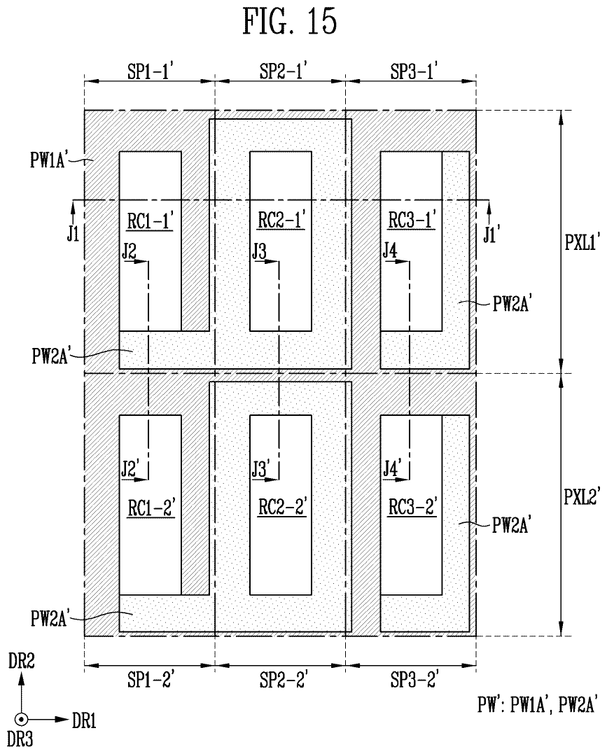

Referring to FIGS. 14 and 15, various components may be disposed in an area where first and second pixels PXL1′ and PXL2′.

The first pixel PXL1′ may include a (1-1)-th sub-pixel (or a 1-1-th sub-pixel) SP1-1′, a (2-1)-th sub-pixel (or a 2-1-th sub-pixel) SP2-1′, and a (3-1)-th sub-pixel (or a 3-1-th sub-pixel) SP3-1′.

The (1-1)-th sub-pixel SP1-1′ may be a red sub-pixel emitting light of red color. The (2-1)-th sub-pixel SP2-1′ may be a green sub-pixel emitting light of green color. The (3-1)-th sub-pixel SP3-1′ may be a blue sub-pixel emitting light of blue color.

The (1-1)-th sub-pixel SP1-1′, the (2-1)-th sub-pixel SP2-1′, and the (3-1)-th sub-pixel SP3-1′ may be disposed along the first direction DR1. However, embodiments are not limited thereto. For example, the (1-1)-th sub-pixel SP1-1′, the (2-1)-th sub-pixel SP2-1′, and the (3-1)-th sub-pixel SP3-1′ may be disposed in a zigzag manner.

The second pixel PXL2′ may be a pixel adjacent to the first pixel PXL1′. For example, the first pixel PXL1′ may be a pixel adjacent to the second pixel PXL2′ in the second direction DR2.

The second pixel PXL2′ may be substantially the same or similar to the first pixel PXL1′. The second pixel PXL2′ may include a (1-2)-th sub-pixel (or a 1-2-th sub-pixel) SP1-2′, a (2-2)-th sub-pixel (or a 2-2-th sub-pixel) SP2-2′, and a (3-2)-th sub-pixel (or a 3-2-th sub-pixel) SP3-2′.

The (1-2)-th sub-pixel SP1-2′ may be a red sub-pixel emitting light of red color. The (2-2)-th sub-pixel SP2-2′ may be a green sub-pixel emitting light of green color. The (3-2)-th sub-pixel SP3-2′ may be a blue sub-pixel emitting light of blue color.

The (1-2)-th sub-pixel SP1-2′, the (2-2)-th sub-pixel SP2-2′, and the (3-2)-th sub-pixel SP3-2′ may be disposed along the first direction DR1. However, embodiments are not limited thereto. In other embodiments, the (1-2)-th sub-pixel SP1-2′, the (2-2)-th sub-pixel SP2-2′, and the (3-2)-th sub-pixel SP3-2′ may be disposed in a zigzag manner.

The (1-1)-th sub-pixel SP1-1′ may be a sub-pixel adjacent to the (1-2)-th sub-pixel SP1-2′ in the second direction DR2. The (2-1)-th sub-pixel SP2-1′ may be a sub-pixel adjacent to the (2-2)-th sub-pixel SP2-2′ in the second direction DR2. The (3-1)-th sub-pixel SP3-1′ may be a sub-pixel adjacent to the (3-2)-th sub-pixel SP3-2′ in the second direction DR2.

In FIGS. 14 and 15, for clarity and a concise description, only two pixels PXL1′ and PXL2′ are shown, but multiple pixels may be provided. For example, a third pixel adjacent to the first pixel PXL1′ in a direction opposite to the first direction DR1, a fourth pixel adjacent to the first pixel PXL1′ in the first direction DR1, and the like may be provided. The pixels may be substantially the same or similar to each other.

In FIG. 14, a color filter layer CF′ may be disposed in an area where the first and second pixels PXL1′ and PXL2′ are provided.

The color filter layer CF′ may include a first color filter layer RCF′ including a first color filter material, a second color filter layer GCF′ including a second color filter material, and a third color filter layer BCF′ including a third color filter material.

The first color filter layer RCF′ and the first color filter layer RCF described with reference to FIG. 7 may have the same planar shape (e.g., substantially the same or similar planar shape). For example, the first color filter layer RCF′ may include red openings overlapping a (2-1)-th receiving opening (or a 2-1-th receiving opening) RC2-1′, a (2-2)-th receiving opening (or a 2-2-th receiving opening) RC2-2′, a (3-1)-th receiving opening (or a 3-1-th receiving opening) RC3-1′, and a (3-2)-th receiving opening (or a 3-2-th receiving opening) RC3-2′ in a plan view. Hereinafter, detailed description of the same constituent elements is omitted.

The second color filter layer GCF′ and the second color filter layer GCF described with reference to FIG. 8 may have the same planar shape (e.g., substantially the same or similar planar shape). For example, the second color filter layer GCF′ may include green openings overlapping the (1-1)-th receiving opening RC1-1′, the (1-2)-th receiving opening RC1-2′, the (3-1)-th receiving opening RC3-1′, and the (3-2)-th receiving opening RC3-2′ in a plan view. Hereinafter, detailed description of the same constituent elements is omitted.

The third color filter layer BCF′ and the third color filter layer BCF described with reference to FIG. 6 may have the same planar shape (e.g., substantially the same or similar planar shape). For example, the third color filter layer BCF′ may include blue openings overlapping the (1-1)-th receiving opening RC1-1′, the (1-2)-th receiving opening RC1-2′, the (2-1)-th receiving opening RC2-1′, and the (2-2)-th receiving opening RC2-2′ in a plan view. Hereinafter, detailed description of the same or similar constituent elements is omitted.

The first color filter layer RCF′ may be disposed on the third color filter layer BCF′. The second color filter layer GCF′ may be disposed on the first color filter layer RCF′. However, the disclosure is not limited thereto, and a stack order of the first to third color filter layers RCF′, GCF′, and BCF′ may be variously changed.

In FIG. 15, a partition wall member PW′ may be disposed in an area where the first and second pixels PXL1′ and PXL2′ are provided.

The partition wall member PW′ may be disposed on the color filter layer CF′ described with reference to FIG. 14.

The partition wall member PW′ may include the (1-1)-th receiving opening RC1-1′ disposed in an area where the (1-1)-th sub-pixel SP1-1′ is provided, the (1-2)-th receiving opening RC1-2′ disposed in an area where the (1-2)-th sub-pixel SP1-2′ is provided, the (2-1)-th receiving opening RC2-1′ disposed in an area where the (2-1)-th sub-pixel SP2-1′ is provided, the (2-2)-th receiving opening RC2-2′ disposed in an area where the (2-2)-th sub-pixel SP2-2′ is provided, the (3-1)-th receiving opening RC3-1′ disposed in an area where the (3-1)-th sub-pixel SP3-1′ is provided, and the (3-2)-th receiving opening RC3-2′ disposed in an area where the (3-2)-th sub-pixel SP3-2′ is provided.

The (1-1)-th receiving opening RC1-1′, the (1-2)-th receiving opening RC1-2′, the (2-1)-th receiving opening RC2-1′, the (2-2)-th receiving opening RC2-2′, the (3-1)-th receiving opening RC3-1′, and the (3-2)-th receiving opening RC3-2′ may be spaced apart from each other.

In an embodiment, the partition wall member PW′ may include a first partition wall member PW1A′ and a second partition wall member PW2A′. The first partition wall member PW1A′ and the first partition wall member PW1A described with reference to FIG. 4 may have the same planar shape (e.g., substantially the same or similar planar shape). The second partition wall member PW2A′ and the second partition wall member PW2A described with reference to FIG. 5 may have the same planar shape (e.g., substantially the same or similar planar shape). Hereinafter, detailed description of the same or similar constituent elements is omitted.

The first partition wall member PW1A′ may include a first color filter material included in the first color filter RCF′ (e.g., refer to FIG. 14). The first partition wall member PW1A′ and the first color filter RCF′ may have the same function (e.g., substantially the same or similar function). For example, the first partition wall member PW1A′ may selectively transmit light of red color.

The second partition wall member PW2A′ may include a second color filter material included in the second color filter GCF′ (e.g., refer to FIG. 14). The second partition wall member PW2A′ and the second color filter GCF′ may have the same function (e.g., substantially the same or similar function). For example, the second partition wall member PW2A′ may selectively transmit light of green color.

In an embodiment, each of the first and second partition wall members PW1A′ and PW2A′ may further include a liquid repellent material (e.g., a hydrophobic material). Accordingly, in an inkjet process for forming color conversion layers LCL1-1′, LCL1-2′, LCL2-1′, and LCL2-2′ and scattering layers LSL1-1′ and LSL1-2′, the color conversion layers LCL1-1′, LCL1-2′, LCL2-1′, and LCL2-2′ and the scattering layers LSL1-1′ and LSL1-2′ may be effectively provided in the receiving openings RC1-1′, RC1-2′, RC2-1′, RC2-2′, RC3-1′, and RC3-2′.

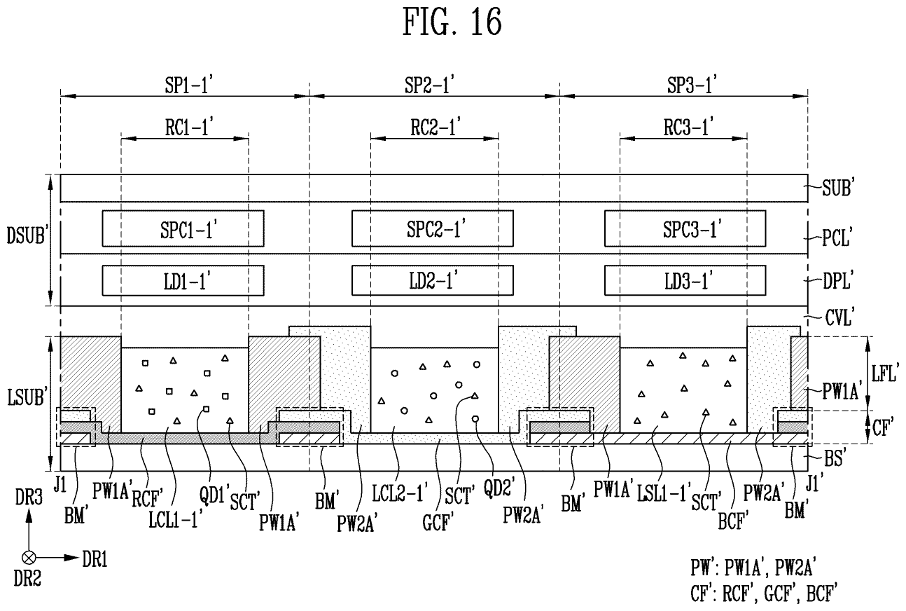

In FIG. 16, a cross-sectional view taken along line J1-J1′ of FIG. 15 is shown.

Referring to FIG. 16, the display device DD (or the display panel DP of FIG. 1) may include a color conversion substrate LSUB′, a display substrate DSUB′ facing the color conversion substrate LSUB′, and a filling layer CVL′ disposed (e.g., interposed) between the color conversion substrate LSUB′ and the display substrate DSUB′.

The display substrate DSUB′ may include a substrate SUB′, a pixel circuit layer PCL′, and a display element layer DPL′.

The substrate SUB′ may be described similarly to the substrate SUB described with reference to FIG. 10. Therefore, detailed description of the same or similar constituent elements is omitted.

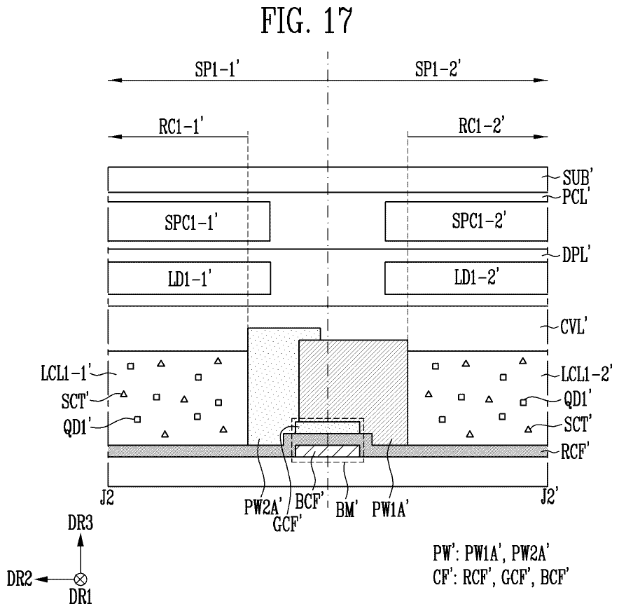

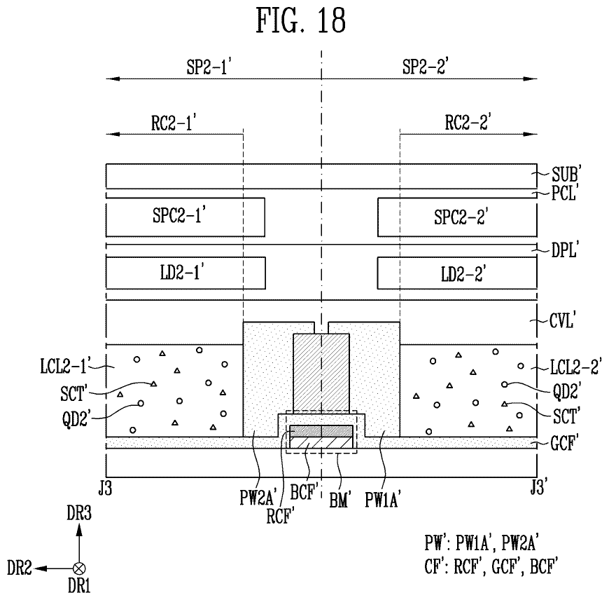

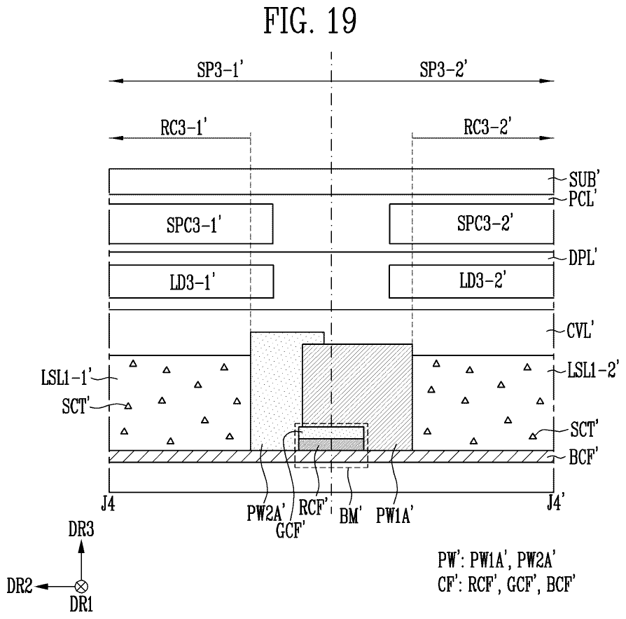

The pixel circuit layer PCL′ may be disposed under the substrate SUB′. The pixel circuit layer PCL′ may be described similarly to the pixel circuit layer PCL described with reference to FIG. 10. For example, transistors, capacitors, and lines included in the pixel circuit layer PCL′ may form the sub-pixel circuit SPC of FIG. 2 of each of the (1-1)-th sub-pixel SP1-1′, the (1-2)-th sub-pixel SP1-2′, the (2-1)-th sub-pixel SP2-1′, the (2-2)-th sub-pixel SP2-2′, the (3-1)-th sub-pixel SP3-1′, and the (3-2)-th sub-pixel SP3-2′. For example, FIG. 16 shows a (1-1)-th sub-pixel circuit (or a 1-1-th sub-pixel circuit) SPC1-1′ of the (1-1)-th sub-pixel SP1-1′, a (2-1)-th sub-pixel circuit (or a 2-1-th sub-pixel circuit) SPC2-1′ of the (2-1)-th sub-pixel SP2-1′, and a (3-1)-th sub-pixel circuit (or a 3-1-th sub-pixel circuit) SPC3-1′ of the (3-1)-th sub-pixel SP3-1′. FIG. 17 shows a (1-2)-th sub-pixel circuit (or a 1-2-th sub-pixel circuit) SPC1-2′ of the (1-2)-th sub-pixel SP1-2′. FIG. 18 shows a (2-2)-th sub-pixel circuit (or a 2-2-th sub-pixel circuit) SPC2-2′ of the (2-2)-th sub-pixel SP2-2′. FIG. 19 shows a (3-2)-th sub-pixel circuit (or a 3-2-th sub-pixel circuit) SPC3-2′ of the (3-2)-th sub-pixel SP3-2′.

The display element layer DPL′ may be disposed under the pixel circuit layer PCL′. The display element layer DPL′ may be described similarly to the display element layer DPL described with reference to FIG. 10. For example, the display element layer DPL′ may include the light emitting element LD of FIG. 2 of each of the (1-1)-th sub-pixel SP1-1′, the (1-2)-th sub-pixel SP1-2′, the (2-1)-th sub-pixel SP2-1′, the (2-2)-th sub-pixel SP2-2′, the (3-1)-th sub-pixel SP3-1′, and the (3-2)-th sub-pixel SP3-2′. For example, FIG. 16 shows a (1-1)-th light emitting element (or a 1-1-th light emitting element) LD1-1′ of the (1-1)-th sub-pixel SP1-1′, a (2-1)-th light emitting element (or a 2-1-th light emitting element) LD2-1′ of the (2-1)-th sub-pixel SP2-1′, and a (3-1)-th light emitting element (or a 3-1-th light emitting element) LD3-1′ of the (3-1)-th sub-pixel SP3-1′. FIG. 17 shows a (1-1)-th light emitting element (or a 1-1-th light emitting element) LD1-1′ of the (1-1)-th sub-pixel SP1-1′ and a (1-2)-th light emitting element (or a 1-2-th light emitting element) LD1-2′ of the (1-2)-th sub-pixel SP1-2′. FIG. 18 shows a (2-1)-th light emitting element (a 2-1-th light emitting element) LD2-1′ of the (2-1)-th sub-pixel SP2-1′ and a (2-2)-th light emitting element (or a 2-2-th light emitting element) LD2-2′ of the (2-2)-th sub-pixel SP2-2′. FIG. 19 shows a (3-1)-th light emitting element (or a 3-1-th light emitting element) LD3-1′ of the (3-1)-th sub-pixel SP3-1′ and a (3-2)-th light emitting element (or a 3-2-th light emitting element) LD3-2′ of the (3-2)-th sub-pixel SP3-2′.

The (1-1)-th light emitting element LD1-1′ may be electrically connected to the (1-1)-th sub-pixel circuit SPC1-1′. The (2-1)-th light emitting element LD2-1′ may be electrically connected to the (2-1)-th sub-pixel circuit SPC2-1′. The (3-1)-th light emitting element LD3-1′ may be electrically connected to the (3-1)-th sub-pixel circuit SPC3-1′. The (1-1)-th light emitting element LD1-1′, the (2-1)-th light emitting element LD2-1′, and the (3-1)-th light emitting element LD3-1′ may emit light of a luminance corresponding to an electric signal provided from the (1-1)-th sub-pixel circuit SPC1-1′, the (2-1)-th sub-pixel circuit SPC2-1′, and the (3-1)-th sub-pixel circuit SPC3-1′.

For example, the (1-2)-th light emitting element LD1-2′ shown in FIG. 17 may be electrically connected to the (1-2)-th sub-pixel circuit SPC1-2′ and may emit light of a luminance corresponding to an electric signal provided from the (1-2)-th sub-pixel circuit SPC1-2′. The (2-2)-th light emitting element LD2-2′ shown in FIG. 18 may be electrically connected to the (2-2)-th sub-pixel circuit SPC2-2′ and may emit light of a luminance corresponding to an electric signal provided from the (2-2)-th sub-pixel circuit SPC2-2′. The (3-2)-th light emitting element LD3-2′ shown in FIG. 19 may be electrically connected to the (3-2)-th sub-pixel circuit SPC3-2′ and may emit light of a luminance corresponding to an electric signal provided from the (3-2)-th sub-pixel circuit SPC3-2′.

In an embodiment, the (1-1)-th light emitting element LD1-1′, the (2-1)-th light emitting element LD2-1′, the (3-1)-th light emitting element LD3-1′, the (1-2)-th light emitting element LD1-2′, the (2-2)-th light emitting element LD2-2′, and the (3-2)-th light emitting element LD3-2′ may emit light of the same color (for example, blue).

The color conversion substrate LSUB′ may include a base substrate BS′, a color filter layer CF′, and a light functional layer LFL′.

The base substrate BS' may provide (or form) a base on which the color filter layer CF′ and the light functional layer LFL′ are disposed. The base substrate BS' may include a transparent material and satisfy a light transmittance (e.g., a predetermined or selectable light transmittance). For example, light may pass through the base substrate BS′.

The color filter layer CF′ may be disposed on the base substrate BS′. The color filter layer CF′ may include a first color filter layer RCF′ including a first color filter material, a second color filter layer GCF′ including a second color filter material, and a third color filter layer BCF′ including a third color filter material.

In an embodiment, a light blocking member BM′ may have a triple-layer structure in which the first to third color filter layers RCF′, GCF′, and BCF′ are stacked each other. The light blocking member BM′ may block light since the light blocking member BM′ has a structure in which the first to third color filter layers RCF′, GCF′, and BCF′ including the first to third color filter materials are stacked each other. The light blocking member BM′ may be disposed between adjacent sub-pixels (e.g., adjacent ones of the sub-pixels) and prevent light mixing between the adjacent sub-pixels (e.g., the adjacent ones of the sub-pixels). In an embodiment, between sub-pixels adjacent in the first direction DR1, a width of the light blocking member BM′ may be less than a width of the partition wall member PW′ in the first direction DR1.

The light functional layer LFL′ may be disposed on the color filter layer CF′. The light functional layer LFL′ may include the partition wall member PW′, the (1-1)-th color conversion layer LCL1-1′, the (2-1)-th color conversion layer LCL2-1′, and the (1-1)-th scattering layer LSL1-1′.

The partition wall member PW′ may be disposed on the color filter layer CF′. In an embodiment, the partition wall member PW′ may be directly disposed on the color filter layer CF′. The partition wall member PW′ may include the first partition wall member PW1A′ including the first color filter material and the second partition wall member PW2A′ including the second color filter material. In an embodiment, in a partial area, the second partition wall member PW2A′ may cover an upper surface of the first partition wall member PW1A′. For example, a portion of the second partition wall member PW2A′ may be disposed on a portion of the first partition wall member PW1A′.

The partition wall member PW′ may include a (1-1)-th receiving opening (or a 1-1-th receiving opening) RC1-1′, a (2-1)-th receiving opening (or a 2-1-th receiving opening) RC2-1′, and a (3-1)-th receiving opening (or a 3-1-th receiving opening) RC3-1′ exposing the color filter layer CF′. For example, the color filter layer CF′ may be exposed through the (1-1)-th receiving opening RC1-1′, the (2-1)-th receiving opening RC2-1′, and the (3-1)-th receiving opening RC3-1′.

The (1-1)-th receiving opening RC1-1′ may overlap the (1-1)-th light emitting element LD1-1′ in a plan view and may expose the first color filter layer RCF′. The (1-1)-th receiving opening RC1-1′ may not overlap the second color filter layer GCF′ and the third color filter layer BCF′ in a plan view.

The (2-1)-th receiving opening RC2-1′ may overlap the (2-1)-th light emitting element LD2-1′ in a plan view and may expose the second color filter layer GCF′. The (2-1)-th receiving opening RC2-1′ may not overlap the first color filter layer RCF′ and the third color filter layer BCF′ in a plan view.

The (3-1)-th receiving opening RC3-1′ may overlap the (3-1)-th light emitting element LD3-1′ in a plan view and may expose the third color filter layer BCF′. The (3-1)-th receiving opening RC3-1′ may not overlap the first color filter layer RCF′ and the third color filter layer GCF′ in a plan view′.

The (1-1)-th color conversion layer LCL1-1′ may be disposed in the (1-1)-th receiving opening RC1-1′. In an embodiment, the (1-1)-th color conversion layer LCL1-1′ may be disposed (e.g., directly disposed) on the first color filter layer RCF′ exposed by the (1-1)-th receiving opening RC1-1′.

The (1-1)-th color conversion layer LCL1-1′ may include first color conversion particles QD1′. The first color conversion particles QD1′ may change a color (or wavelength) of light emitted from the (1-1)-th light emitting element LD1-1′. For example, the first color conversion particles QD1′ may convert light emitted from the (1-1)-th light emitting element LD1-1′ into light of red color. Accordingly, the (1-1)-th sub-pixel SP1-1′ may be provided as (or may form) a red sub-pixel. In embodiments, the first color conversion particles QD1′ may be quantum dots. In an embodiment, the (1-1)-th color conversion layer LCL1-1′ may further include scattering particles SCT′ that scatters light.

The (2-1)-th color conversion layer LCL2-1′ may be disposed in the (2-1)-th receiving opening RC2-1′. In an embodiment, the (2-1)-th color conversion layer LCL2-1′ may be disposed (e.g., directly disposed) on the second color filter layer GCF′ exposed by the (2-1)-th receiving opening RC2-1′.

The (2-1)-th color conversion layer LCL2-1′ may include second color conversion particles QD2′. The second color conversion particles QD2′ may change a color (or wavelength) of light emitted from the (2-1)-th light emitting element LD2-1′. For example, the second color conversion particles QD2′ may convert light emitted from the (2-1)-th light emitting element LD2-1′ into light of green color. Accordingly, the (2-1)-th sub-pixel SP2-1′ may be provided as (or may form) a green sub-pixel. In embodiments, the second color conversion particles QD2′ may be quantum dots. In an embodiment, the (2-1)-th color conversion layer LCL2-1′ may further include scattering particles SCT′ that scatters light.

The (1-1)-th scattering layer LSL1-1′ may be disposed in the (3-1)-th receiving opening RC3-1′. In an embodiment, the (1-1)-th scattering layer LSL1-1′ may be disposed (e.g., directly disposed) on the third color filter layer BCF′ exposed by the (3-1)-th receiving opening RC3-1′.

The (1-1)-th scattering layer LSL1-1′ may include scattering particles SCT′. The scattering particles SCT′ may scatter light emitted from the (3-1)-th light emitting element LD3-1′ and improve light emission efficiency. Accordingly, in case that the (3-1)-th light emitting element LD3-1′ emits light of blue color, the (3-1)-th sub-pixel SP3-1′ may be provided as (or may form) a blue sub-pixel. In an embodiment, the scattering particles SCT′ may include TiO₂.

In an embodiment, the first partition wall member PW1A′ and the second partition wall member PW2A′ may be disposed (e.g., interposed) between the (1-1)-th receiving opening RC1-1′ and the (2-1)-th receiving opening RC2-1′ adjacent to each other. For example, as shown in FIG. 16, the first partition wall member PW1A′ and the second partition wall member PW2A′ may be disposed along the first direction DR1 between the (1-1)-th receiving opening RC1-1′ and the (2-1)-th receiving opening RC2-1′ adjacent to each other. Light of red color provided by the first color conversion particles QD1′ included in the (1-1)-th color conversion layer LCL1-1′ disposed in the (1-1)-th receiving opening RC1-1′ may be blocked by the second partition wall member PW2A′ including the second color filter material. Light of green color provided by the second color conversion particles QD2′ included in the (2-1)-th color conversion layer LCL2-1′ disposed in the (2-1)-th receiving opening RC2-1′ may be blocked by the first partition wall member PW1A′ including the first color filter material. Accordingly, light mixing between the (1-1)-th sub-pixel SP1-1′ and the (2-1)-th sub-pixel SP2-1′ (e.g., the adjacent (2-1)-th sub-pixel SP2-1′) adjacent to each other may be prevented.

In an embodiment, the first partition wall member PW1A′ and the second partition wall member PW2A′ may be disposed (e.g., interposed) between the (2-1)-th receiving opening RC2-1′ and the (3-1)-th receiving opening RC3-1′ adjacent to each other. For example, as shown in FIG. 16, the second partition wall member PW2A′ and the first partition wall member PW1A′ may be disposed along the first direction DR1 between the (2-1)-th receiving opening RC2-1′ and the (3-1)-th receiving opening RC3-1′ adjacent to each other. Light of green color provided by the second color conversion particles QD2′ included in the (2-1)-th color conversion layer LCL2-1′ disposed in the (2-1)-th receiving opening RC2-1′ may be blocked by the first partition wall member PW1A′ including the first color filter material. Light of blue color scattered by the scattering particles SCT′ included in the (1-1)-th scattering layer LSL1-1′ disposed in the (3-1)-th receiving opening RC3-1′ may be blocked by the first and second partition wall members PW1A′ and PW2A′ including the first and second color filter materials. Accordingly, light mixing between the (2-1)-th sub-pixel SP2-1′ and the (3-1)-th sub-pixel SP3-1′ (e.g., the adjacent (3-1)-th sub-pixel SP3-1′) adjacent to each other may be prevented.

In an embodiment, a sub-pixel adjacent to the (1-1)-th sub-pixel SP1-1′ in the direction opposite to the first direction DR1 may be substantially the same or similar to the (3-1)-th sub-pixel SP3-1′. For example, the (3-1)-th sub-pixel SP3-1′ adjacent to the (1-1)-th sub-pixel SP1-1′ may be disposed (or further provided) in the direction opposite to the first direction DR1. The first partition wall member PW1A′ and the second partition wall member PW2A′ may be disposed (e.g., interposed) between the (1-1)-th receiving opening RC1-1′ and the (3-1)-th receiving opening RC3-1′ adjacent to each other. Light of red color provided by the first color conversion particles QD1′ included in the (1-1)-th color conversion layer LCL1-1′ disposed in the (1-1)-th receiving opening RC1-1′ may be blocked by the second partition wall member PW2A′ including the second color filter material. Light of blue color scattered by the scattering particles SCT included in the (1-1)-th scattering layer LSL1-1′ disposed in the (3-1)-th receiving opening RC3-1′ may be blocked by the first and second partition wall members PW1A′ and PW2A′ including the first and second color filter materials. Accordingly, light mixing between the (1-1)-th sub-pixel SP1-1′ and the (3-1)-th sub-pixel SP3-1′ (e.g., the adjacent (3-1)-th sub-pixel SP3-1′) adjacent to each other may be prevented.

The filling layer CVL′ may be disposed (e.g., interposed) between the color conversion substrate LSUB′ and the display substrate DSUB′ to combine the color conversion substrate LSUB′ and the display substrate DSUB′.

In FIG. 17, a cross-sectional view taken along line J2-J2′ of FIG. 15 is shown. Detailed description of the same or similar constituent elements described with reference to FIG. 16 is omitted.

The partition wall member PW′ may include the (1-2)-th receiving opening RC1-2′ exposing the (1-2)-th color filter layer RCF′. The (1-2)-th receiving opening RC1-2′ may not overlap the second color filter layer GCF′ and the third color filter layer BCF′ in a plan view. The (1-2)-th receiving opening RC1-2′ may overlap the (1-2)-th light emitting element LD1-2′ in a plan view.

The (1-2)-th color conversion layer LCL1-2′ may be disposed in the (1-2)-th receiving opening RC1-2′. In an embodiment, the (1-2)-th color conversion layer LCL1-2′ may be disposed (e.g., directly disposed) on the first color filter layer RCF′ exposed by the (1-2)-th receiving opening RC1-2′.

The (1-2)-th color conversion layer LCL1-2′ may be the same or similar to the (1-1)-th color conversion layer LCL1-1′. For example, the (1-2)-th color conversion layer LCL1-2′ may include first color conversion particles QD1′. Accordingly, the (1-2)-th sub-pixel SP1-2′ may be provided as (or may form) a red sub-pixel. In an embodiment, the (1-2)-th color conversion layer LCL1-2′ may further include scattering particles SCT′.

In an embodiment, the first partition wall member PW1A′ and the second partition wall member PW2A′ may be disposed (e.g., interposed) between the (1-1)-th receiving opening RC1-1′and the (1-2)-th receiving opening RC1-2′ adjacent to each other. For example, as shown in FIG. 17, the second partition wall member PW2A′ and the first partition wall member PW1A′ may be disposed along the direction opposite to the second direction DR2 between the (1-1)-th receiving opening RC1-1′ and the (1-2)-th receiving opening RC1-2′ adjacent to each other. Light of red color provided by the first color conversion particles QD1′ included in the (1-1)-th color conversion layer LCL1-1′ disposed in the (1-1)-th receiving opening RC1-1′ may be blocked by the second partition wall member PW2A′ including the second color filter material. Light of red color provided by the first color conversion particles QD1′ included in the (1-2)-th color conversion layer LCL1-2′ disposed in the (1-2)-th receiving opening RC1-2′ may be blocked by the second partition wall member PW2A′ including the second color filter material. Accordingly, light mixing between the (1-1)-th sub-pixel SP1-1′ and the (1-2)-th sub-pixel SP1-2′ (e.g., the adjacent (1-2)-th sub-pixel SP1-2′) adjacent to each other may be prevented.

Between the (1-1)-th sub-pixel SP1-1′ and the (1-2)-th sub-pixel SP1-2′, the light blocking member BM′ defined by the color filter layer CF′ may be disposed. In an embodiment, between the (1-1)-th sub-pixel SP1-1′ and the (1-2)-th sub-pixel SP1-2′, a width of the light blocking member BM′ may be less than a width of the partition wall member PW′ in the second direction DR2.

In FIG. 18, a cross-sectional view taken along line J3-J3′ of FIG. 15 is shown. Detailed description of the same or similar constituent elements described with reference to FIG. 16 is omitted.

The partition wall member PW′ may include the (2-2)-th receiving opening RC2-2′ that exposes an upper surface of the second color filter layer GCF′. The (2-2)-th receiving opening RC2-2′ may not overlap the first color filter layer RCF′ and the third color filter layer BCF′ in a plan view. The (2-2)-th receiving opening RC2-2′ may overlap the (2-2)-th light emitting element LD2-2′ in a plan view.

The (2-2)-th color conversion layer LCL2-2′ may be disposed in the (2-2)-th receiving opening RC2-2′. In an embodiment, the (2-2)-th color conversion layer LCL2-2′ may be disposed (e.g., directly disposed) on the second color filter layer GCF′ exposed by the (2-2)-th receiving opening RC2-2′.

The (2-2)-th color conversion layer LCL2-2′ may be the same or similar to the (2-1)-th color conversion layer LCL2-1′. For example, the (2-2)-th color conversion layer LCL2-2′ may include second color conversion particles QD2′. Accordingly, the (2-2)-th sub-pixel SP2-2′ may be provided as (or may form) a green sub-pixel. In an embodiment, the (2-2)-th color conversion layer LCL2-2′ may further include scattering particles SCT′.

In an embodiment, the first partition wall member PW1A′ and the second partition wall member PW2A′ may be disposed (e.g., interposed) between the (2-1)-th receiving opening RC2-1′ and the (2-2)-th receiving opening RC2-2′ adjacent to each other. For example, a second partition wall member PW2A′, a first partition wall member PW1A′, and another second partition wall member PW2A′ may be disposed in the direction opposite to the second direction DR2 between the (2-1)-th receiving opening RC2-1′ and the (2-2)-th receiving opening RC2-2′ adjacent to each other. Light of green color provided by the second color conversion particles QD2′ included in the (2-1)-th color conversion layer LCL2-1′ disposed in the (2-1)-th receiving opening RC2-1′ may be blocked by the first partition wall member PW1A′ including the first color filter material. Light of green color provided by the second color conversion particles QD2′ included in the (2-2)-th color conversion layer LCL2-2′ disposed in the (2-2)-th receiving opening RC2-2′ may be blocked by the first partition wall member PW1A′ including the first color filter material. Accordingly, light mixing between the (2-1)-th sub-pixel SP2-1′ and the (2-2)-th sub-pixel SP2-2′ (e.g., the adjacent (2-2)-th sub-pixel SP2-2′) adjacent to each other may be prevented.

The light blocking member BM′ defined by the color filter layer CF′ may be disposed between the (2-1)-th sub-pixel SP2-1′ and the (2-2)-th sub-pixel SP2-2′. In an embodiment, between the (2-1)-th sub-pixel SP2-1′ and the (2-2)-th sub-pixel SP2-2′, a width of the light blocking member BM′ may be less than a width of the partition wall member PW′ in the second direction DR2.

In FIG. 19, a cross-sectional view taken along line J4-J4′ of FIG. 15A is shown. Detailed description of the same or similar constituent elements described with reference to FIG. 16 is omitted.

The partition wall member PW′ may include the (3-2)-th receiving opening RC3-2′ exposing the third color filter layer BCF′. The (3-2)-th receiving opening RC3-2′ may not overlap the first color filter layer RCF′ and the second color filter layer GCF′ in a plan view. The (3-2)-th receiving opening RC3-2′ may overlap the (3-2)-th light emitting element LD3-2′ in a plan view.

The (1-2)-th scattering layer LSL1-2′ may be disposed in the (3-2)-th receiving opening RC3-2′. In an embodiment, the (1-2)-th scattering layer LSL1-2′ may be disposed (e.g., directly disposed) on the third color filter layer BCF′ exposed by the (3-2)-th receiving opening RC3-2′.

The (1-2)-th scattering layer LSL1-2′ may be substantially the same or similar to the (1-1)-th scattering layer LSL1-1′. For example, the (1-2)-th scattering layer LSL1-2′ may include scattering particles SCT′. Accordingly, the (3-2)-th sub-pixel SP3-2′ may be provided as (or may form) a blue sub-pixel.

In an embodiment, the first partition wall member PW1A′ and the second partition wall member PW2A′ may be disposed (e.g., interposed) between the (3-1)-th receiving opening RC3-1′ and the (3-2)-th receiving opening RC3-2′ adjacent to each other. For example, the second partition wall member PW2A′ and the first partition wall member PW1A′ may be disposed along the direction opposite to the second direction DR2 between the (3-1)-th receiving opening RC3-1′ and the (3-2)-th receiving opening RC3-2′ adjacent to each other. Light of blue color scattered by the scattering particles SCT′ included in the (1-1)-th scattering layer LSL1-1′ disposed in the (3-1)-th receiving opening RC3-1′ may be blocked by the first and second partition wall members PW1A′ and PW2A′ including the first and second color filter materials. Light of blue color scattered by the scattering particles SCT′ included in the (1-2)-th scattering layer LSL1-2′ disposed in the (3-2)-th receiving opening RC3-2′ may be blocked by the first and second partition wall members PW1A′ and PW2A′ including the first and second color filter materials. Accordingly, light mixing between the (3-1)-th sub-pixel SP3-1′ and the (3-2)-th sub-pixel SP3-2′ (e.g., the adjacent (3-2)-th sub-pixel SP3-2′) adjacent to each other may be prevented.

Between the (3-1)-th sub-pixel SP3-1′ and the (3-2)-th sub-pixel SP3-2′, the light blocking member BM′ defined by the color filter layer CF′ may be disposed. In an embodiment, between the (3-1)-th sub-pixel SP3-1′ and the (3-2)-th sub-pixel SP3-2′, a width of the light blocking member BM′ may be less than a width of the partition wall member PW′ in the second direction DR2.

Referring to FIGS. 14 to 19 again, in the disclosure, the partition wall member PW′ may include the second partition wall member PW2A′ and the first partition wall member PW1A′ including the first color filter material. Accordingly, in case that the partition wall member PW′ is formed, the degree of design freedom of the display device may be improved, and light efficiency of the display device DD may be improved.

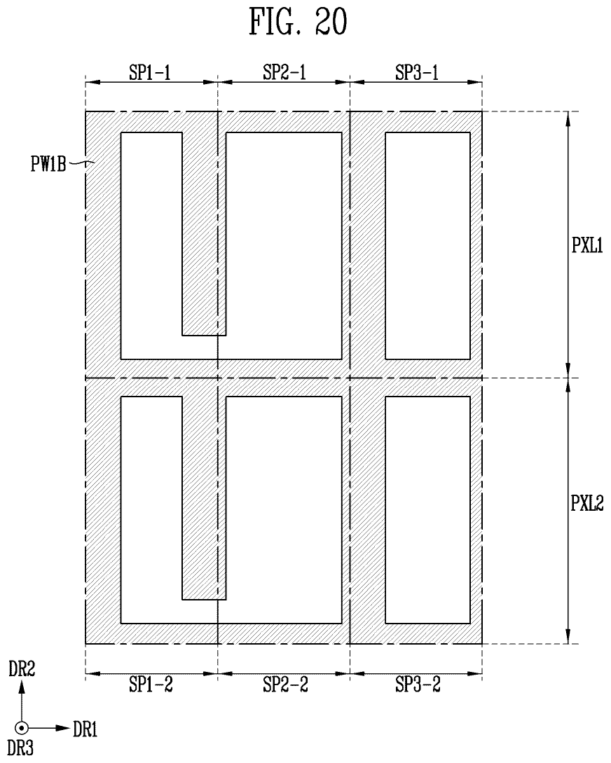

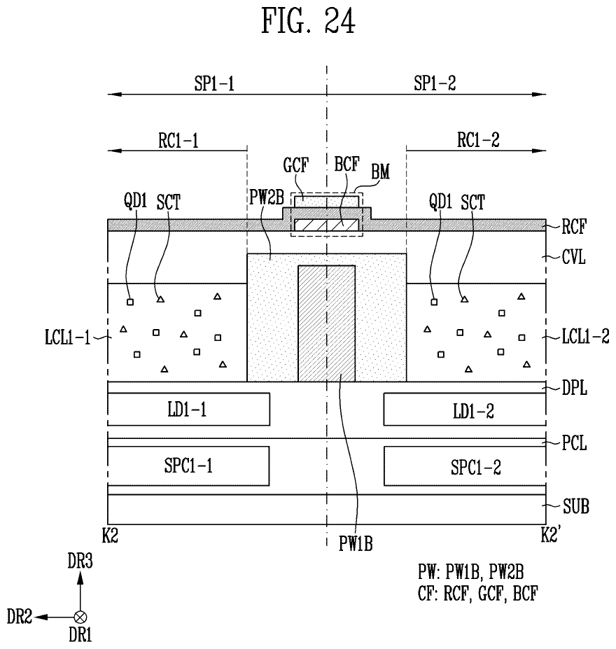

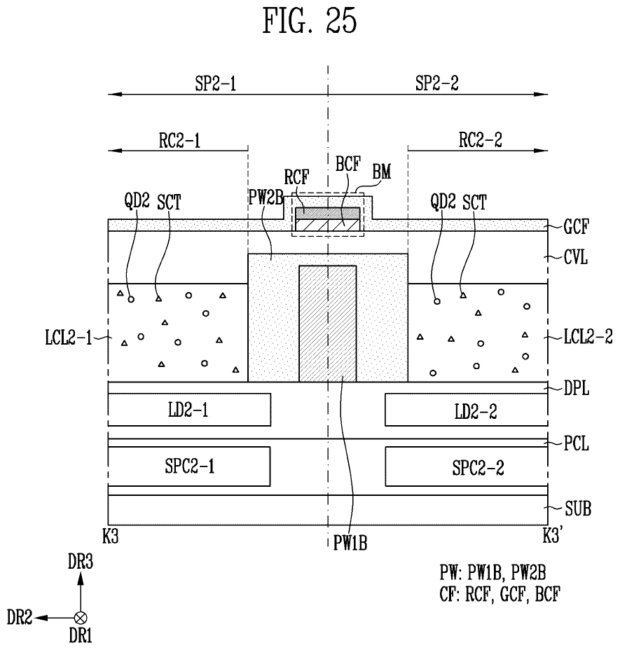

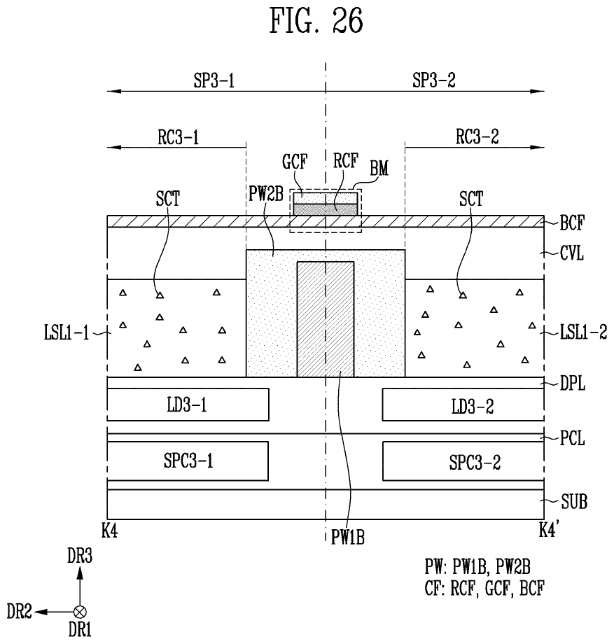

FIGS. 20 to 26 are schematic drawings illustrating an embodiment of the display device described with reference to FIGS. 4 to 13.

In describing FIGS. 20 to 26, a difference compared to the contents described with reference to FIGS. 4 to 13 is described, and detailed description of the same or similar constituent elements is omitted.

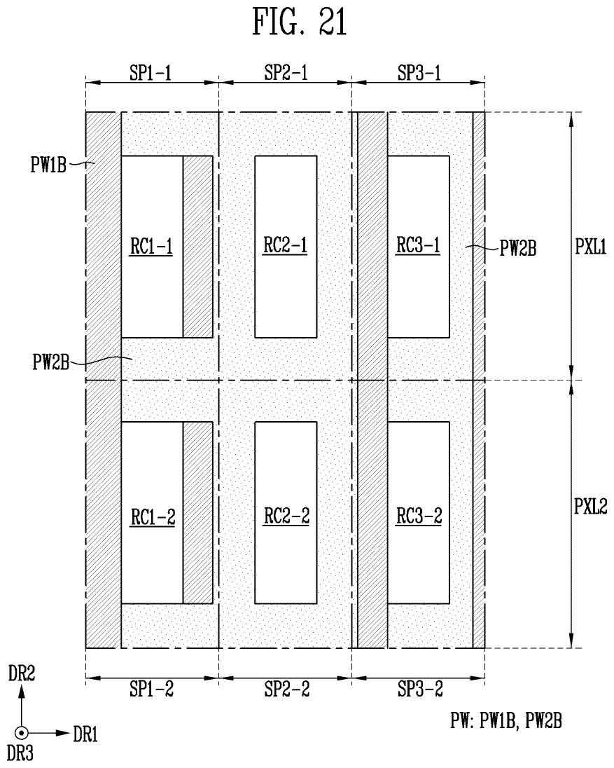

Referring to FIGS. 20 and 21, the partition wall member PW may include a first partition wall member PW1B and a second partition wall member PW2B.

The first partition wall member PW1B and the first partition wall member PW1A may have the same structure. Therefore, detailed description of the same or constituent elements is omitted.

The second partition wall member PW2B may be different from the second partition wall member PW2A at least in that the second partition wall member PW2B is successively formed to cover the first partition wall member PW1B between the (1-1)-th receiving opening RC1-1 and the (1-2)-th receiving opening RC1-2 and between the (2-1)-th receiving opening RC2-1 and the (2-2)-th receiving opening RC2-2, and is successively formed to cover the first partition wall member PW1B between the (3-1)-th receiving opening RC3-1 and the (3-2)-th receiving opening RC3-2. Therefore, detailed description of the same or similar constituent elements is omitted.

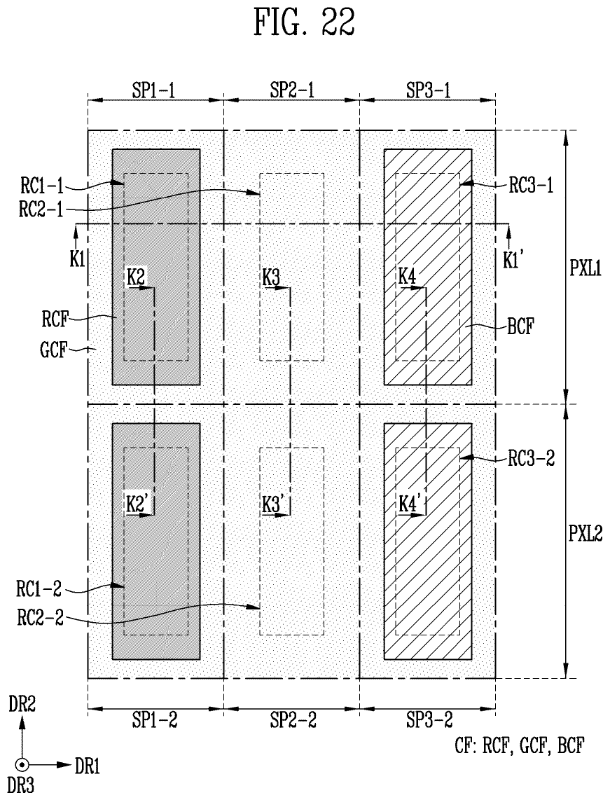

In FIG. 22, the color filter layer CF is shown. The color filter layer CF may be described similarly to that described with reference to FIGS. 6 to 9. Thus, detailed description of the same or similar constituent elements is omitted.

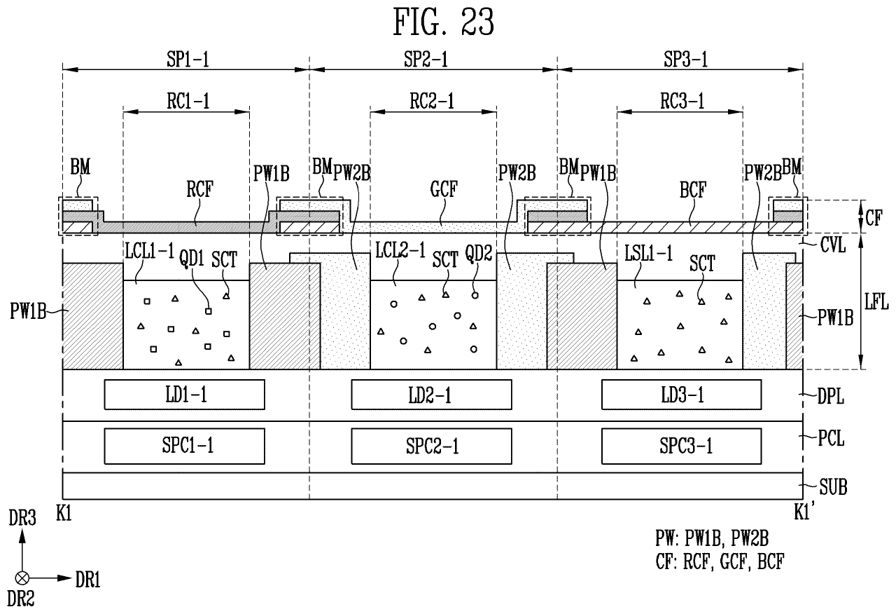

Referring to FIGS. 23 to 26, the second partition wall member PW2B may cover the upper surface (e.g., the entire upper surface) of the first partition wall member PW1B between the (1-1)-th receiving opening RC1-1 and the (1-2)-th receiving opening RC1-2, between the (2-1)-th receiving opening RC2-1 and the (2-2)-th receiving opening RC2-2, and between the (3-1)-th receiving opening RC3-1 and the (3-2)-th receiving opening RC3-2.

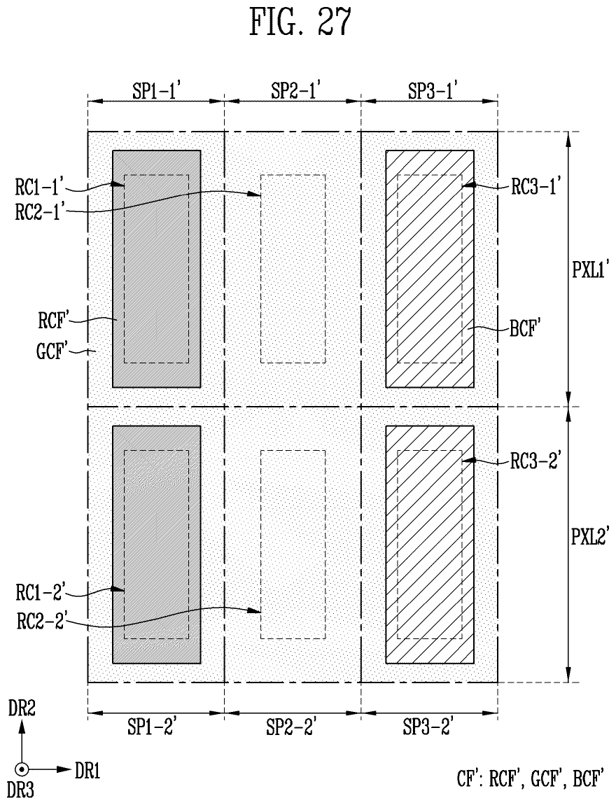

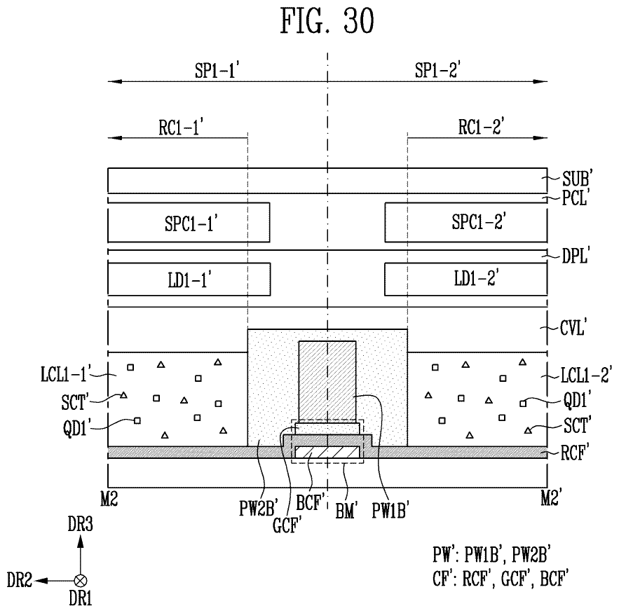

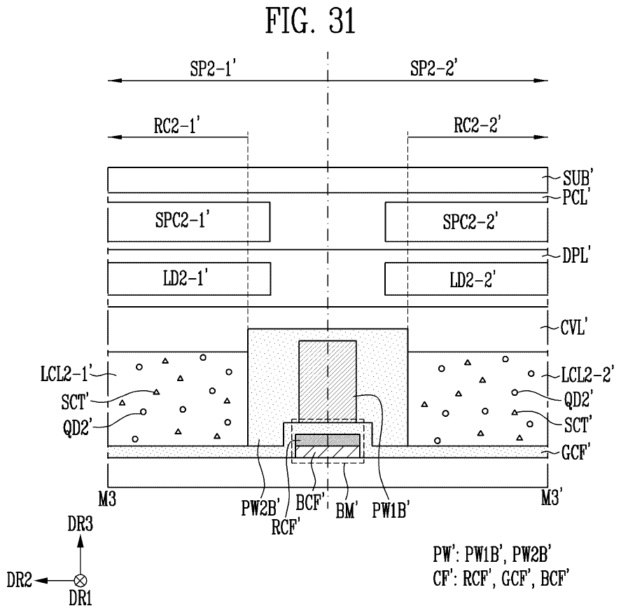

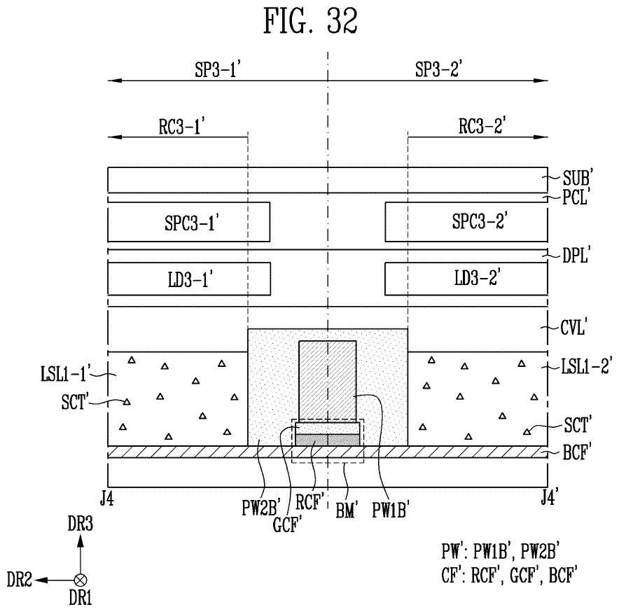

FIGS. 27 to 32 are schematic drawings illustrating an embodiment of the display device described with reference to FIGS. 14 to 19.

In describing FIGS. 27 to 32, a difference compared to the content described with reference to FIGS. 14 to 19 is described, and detailed description of the same or similar constituent elements is omitted.

In FIG. 27, the color filter layer CF′ is shown. The color filter layer CF′ may be described similarly to that described with reference to FIG. 14.

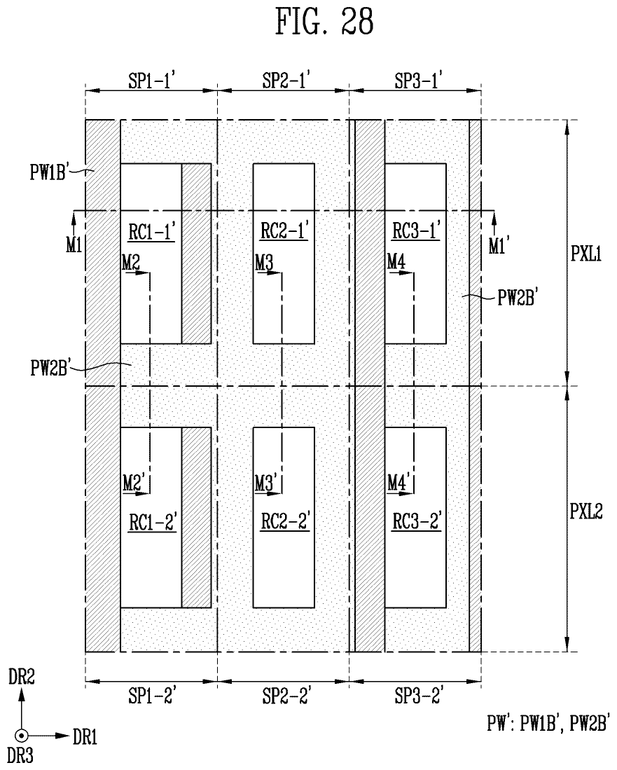

Referring to FIG. 28, the partition wall member PW′ may include a first partition wall member PW1B′ and a second partition wall member PW2B′.

The first partition wall member PW1B′ and the first partition wall member PW1A′ may have the same structure. Therefore, detailed description of the same or similar constituent elements is omitted.

The second partition wall member PW2B′ may be different from the second partition wall member PW2A′ at least in that the second partition wall member PW2B′ is successive formed to cover the first partition wall member PW1B′ between the (1-1)-th receiving opening RC1-1′ and the (1-2)-th receiving opening RC1-2′ and between the (2-1)-th receiving opening RC2-1′ and the (2-2)-th receiving opening RC2-2′, and is successively formed to cover the first partition wall member PW1B′ between the (3-1)-th receiving opening RC3-1′ and the (3-2)-th receiving opening RC3-2′. Therefore, detailed description of the same or similar constituent elements is omitted.

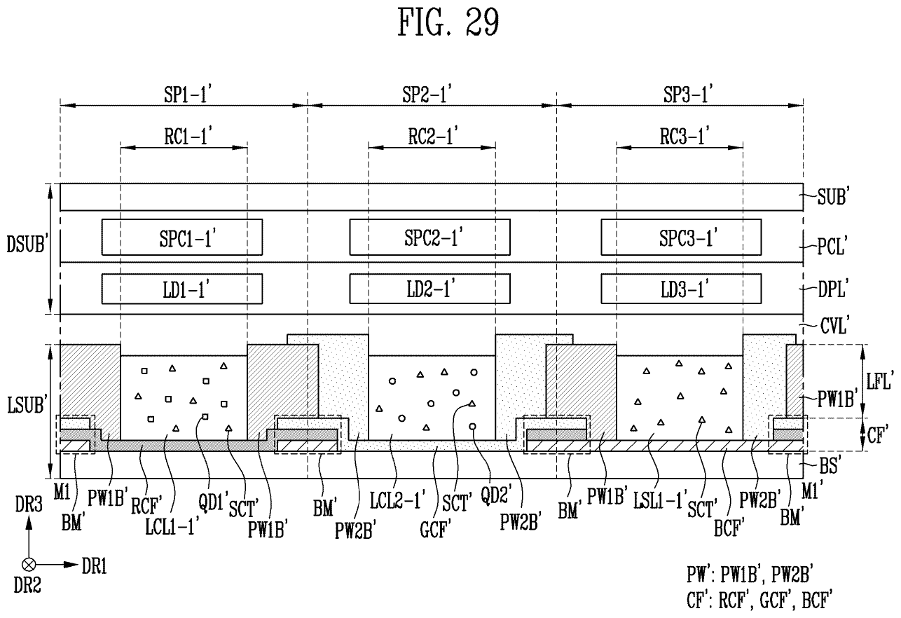

Referring to FIGS. 29 to 32, the second partition wall member PW2B′ may cover the upper surface (e.g., the entire upper surface) of the first partition wall member PW1B′ between the (1-1)-th receiving opening RC1-1′ and the (1-2)-th receiving opening RC1-2′, between the (2-1)-th receiving opening RC2-1′ and the (2-2)-th receiving opening RC2-2′, and between the (3-1)-th receiving opening RC3-1′ and the (3-2)-th receiving opening RC3-2′.

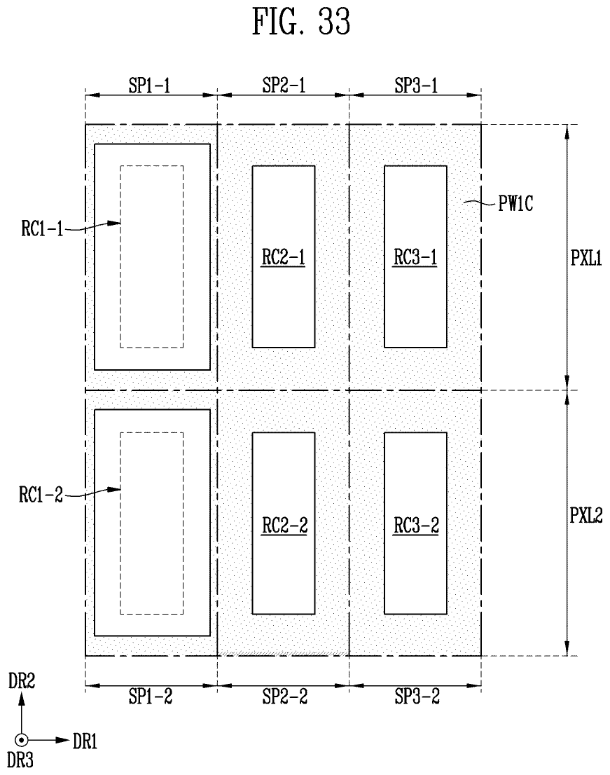

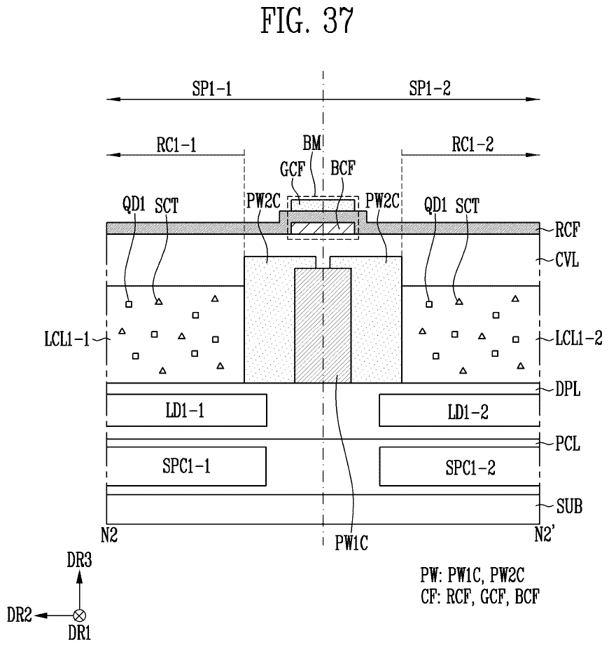

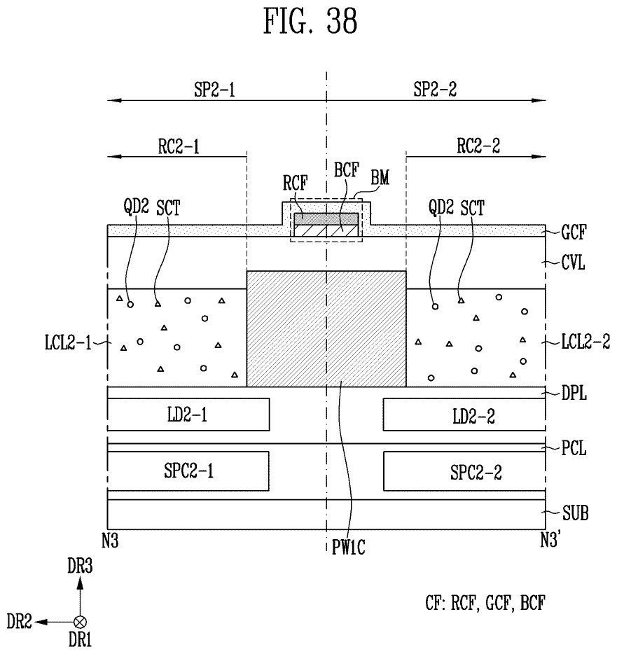

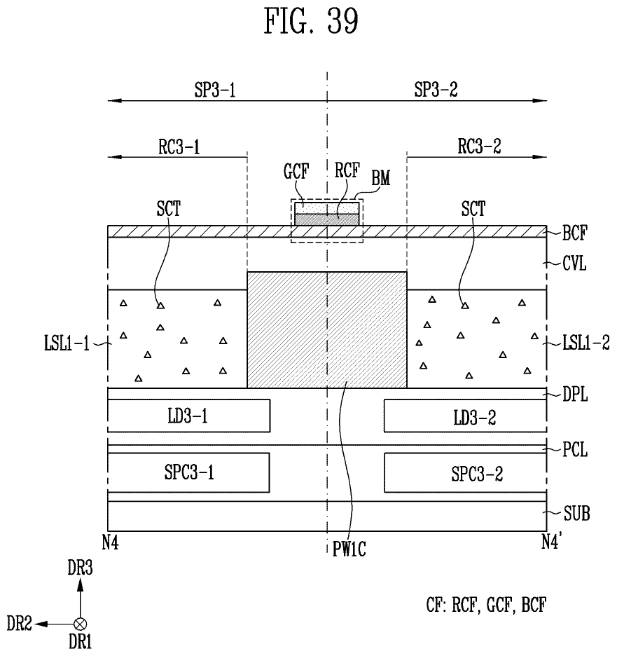

FIGS. 33 to 39 are schematic drawings illustrating an embodiment of the display device described with reference to FIGS. 4 to 13.

In describing FIGS. 33 to 39, a difference compared to the content described with reference to FIGS. 4 to 13 is described, and detailed description of the same or similar constituent elements is omitted.

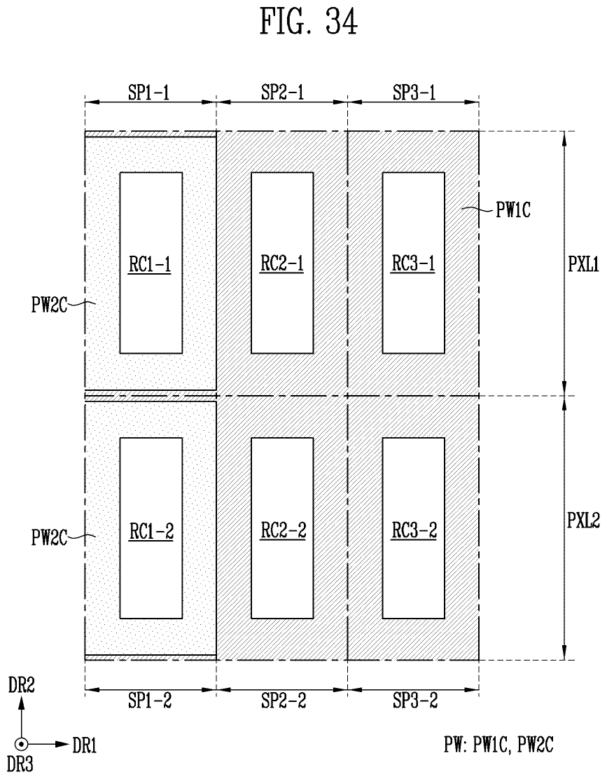

Referring to FIGS. 33 and 34, the partition wall member PW may include a first partition wall member PW1C and a second partition wall member PW2C.

The first partition wall member PWIC may be different from the first partition wall member PW1A at least in a planar shape. The first partition wall member PW1C may include a (2-1)-th receiving opening (or a 2-1-th receiving opening) RC2-1, a (2-2)-th receiving opening (or a 2-2-th receiving opening) RC2-2, a (3-1)-th receiving opening (or a 3-1-th receiving opening) RC3-1, and a (3-2)-th receiving opening (or a 3-2-th receiving opening) RC3-2. The first partition wall member PWIC may include openings adjacent to (e.g., surrounding) the (1-1)-th receiving opening RC1-1 and the (1-2)-th receiving opening RC1-2.

The second partition wall member PW2C may be different from the second partition wall member PW2A at least in a planar shape. The second partition wall member PW2C may be disposed in the openings of the first partition wall member PWIC. The second partition wall member PW2C may include a (1-1)-th receiving opening (or a 1-1-th receiving opening) RC1-1 and a (1-2)-th receiving opening (or a 1-2-th receiving opening) RC1-2.

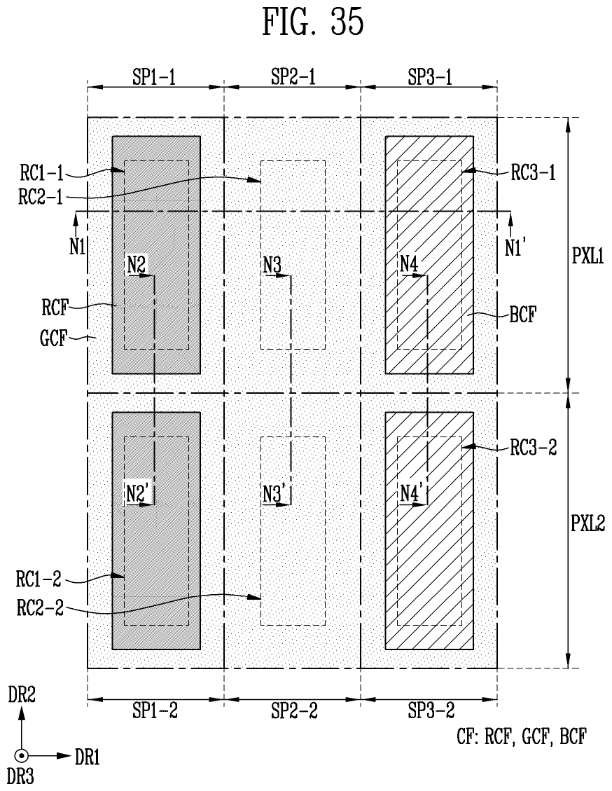

In FIG. 35, the color filter layer CF is shown. The color filter layer CF may be described similarly to that described with reference to FIGS. 6 to 9.

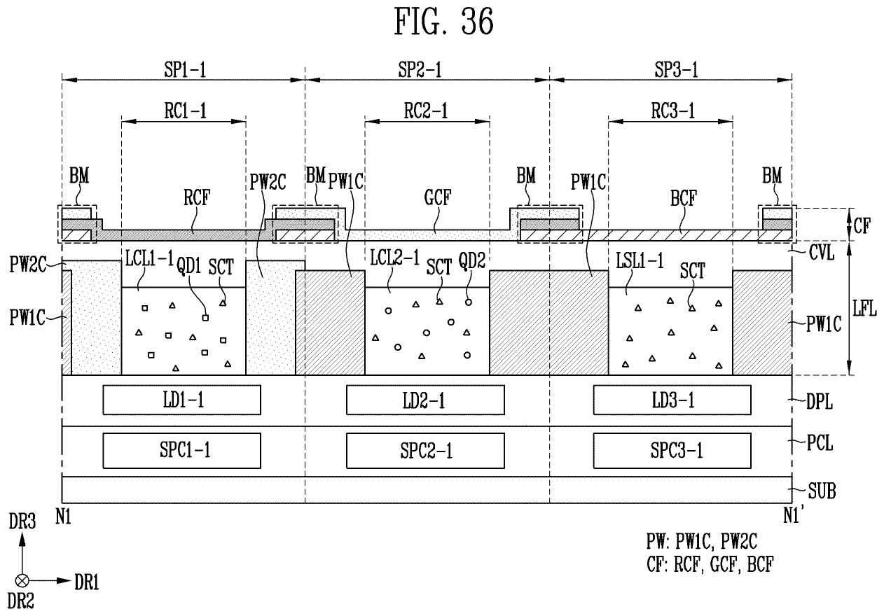

Referring to FIGS. 36 to 39, the first partition wall member PWIC and the second partition wall member PW2C may be disposed (e.g., interposed) between a receiving opening of a red sub-pixel and a receiving opening of another sub-pixel adjacent to each other. For example, the second partition wall member PW2C and the first partition wall member PWIC may be disposed (e.g., interposed) between the (1-1)-th receiving opening RC1-1 and the (2-1)-th receiving opening RC2-1 adjacent to each other. For example, a second partition wall member PW2C, a first partition wall member PW1C, and another second partition wall member PW2C may be disposed (e.g., interposed) between the (1-1)-th receiving opening RC1-1 and the (1-2)-th receiving opening RC2-1 adjacent to each other.

In other embodiments, only the first partition wall member PW1C may be disposed (e.g., interposed) between a receiving opening of a green sub-pixel (or a receiving opening of a blue sub-pixel) and a receiving opening of another green sub-pixel (or a receiving opening of another blue sub-pixel) adjacent to each other. For example, only the first partition wall member PWIC may be disposed (e.g., interposed) between the (2-1)-th receiving opening RC2-1 and the (3-1)-th receiving opening RC3-1 adjacent to each other, between the (2-1)-th receiving opening RC2-1 and the (2-2)-th receiving opening RC2-2 adjacent to each other, and between the (3-1)-th receiving opening RC3-1 and the (3-2)-th receiving opening RC3-2 adjacent to each other.

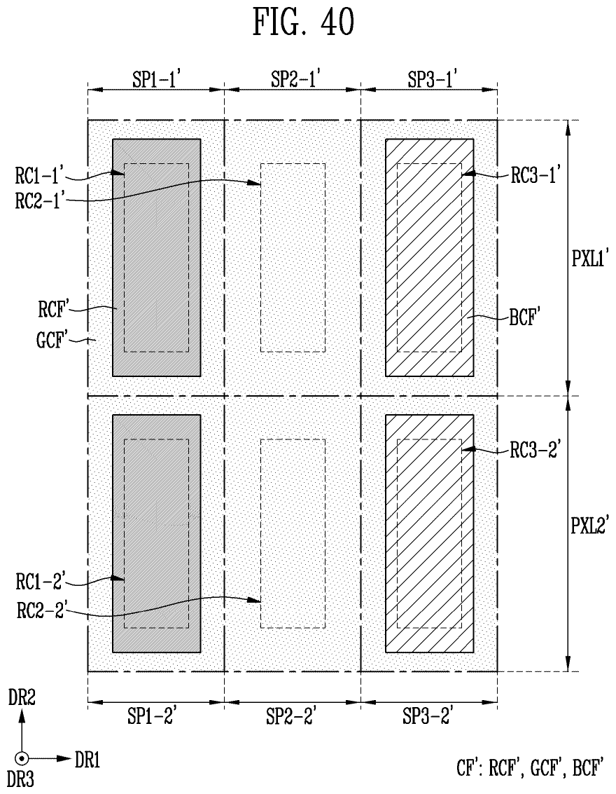

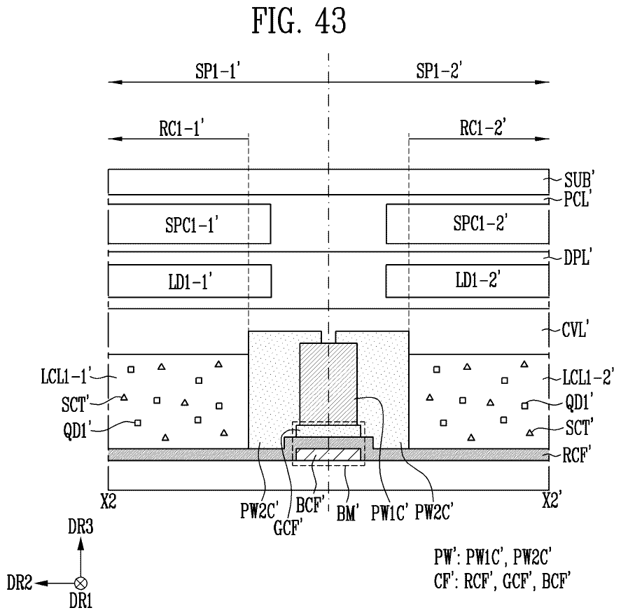

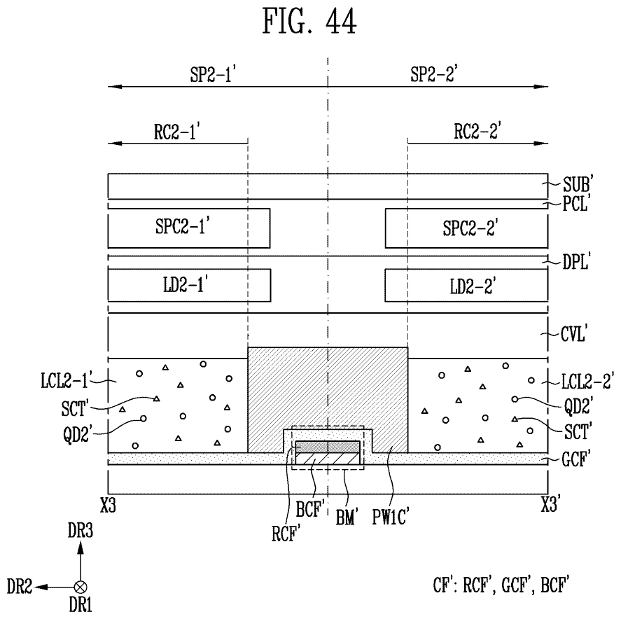

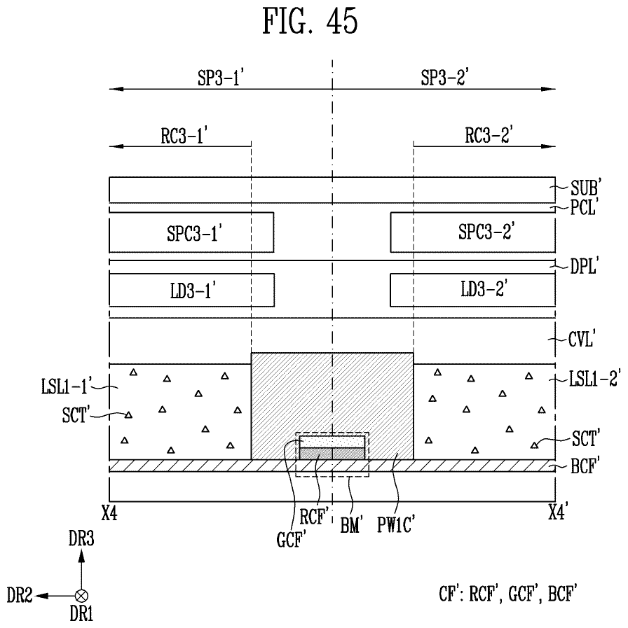

FIGS. 40 to 45 are schematic drawings illustrating an embodiment of the display device described with reference to FIGS. 14 to 19.

In describing FIGS. 40 to 45, a difference compared to the content described with reference to FIGS. 14 to 19 is explained, and detailed description of the same or similar constituent elements is omitted.

In FIG. 40, the color filter layer CF′ is shown. The color filter layer CF′ may be described similarly to that described with reference to FIG. 14.

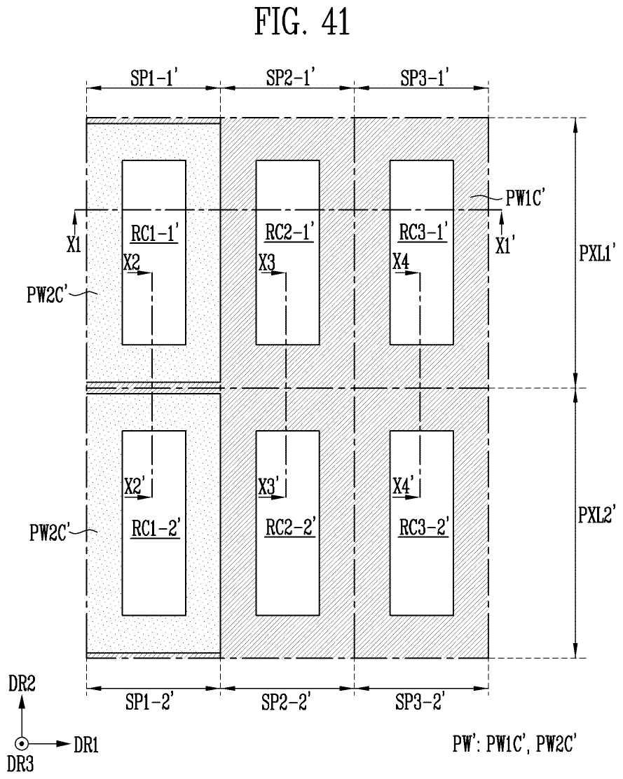

Referring to FIG. 41, the partition wall member PW′ may include a first partition wall member PW1C′ and a second partition wall member PW2C′.

The first partition wall member PWIC′ may be different from the first partition wall member PW1A′ (e.g., refer to FIG. 15) at least in a planar shape. The first partition wall member PW1C′ and the first partition wall member PW1C (e.g., refer to FIG. 34) may have the same planar shape.

The second partition wall member PW2C′ may be different from the second partition wall member PW2A′ (e.g., refer to FIG. 19) at least in a planar shape. The second partition wall member PW2C′ and the second partition wall member PW2C (e.g., refer to FIG. 34) may have the same shape.

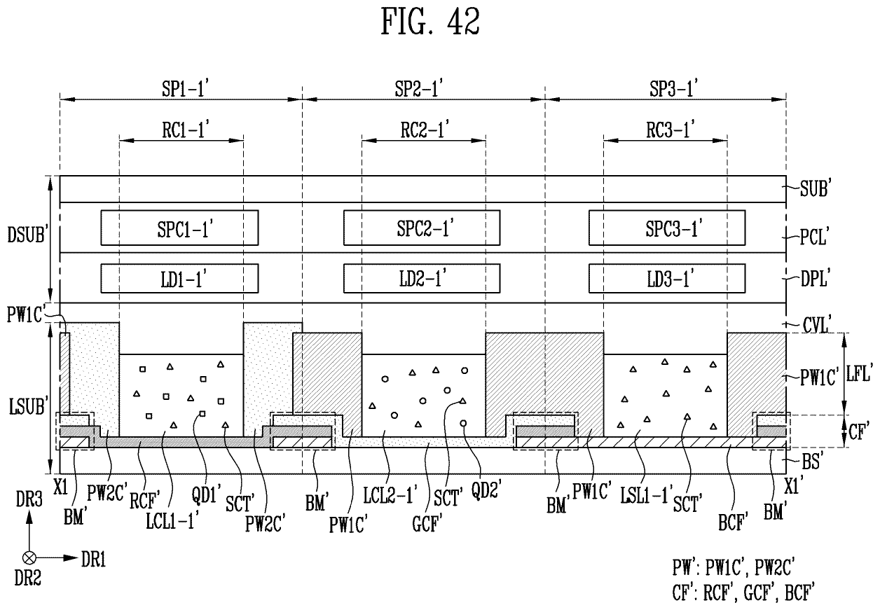

Referring to FIGS. 42 to 45, the first partition wall member PWIC′ and the second partition wall member PW2C′ may be disposed (e.g., interposed) between a receiving opening of a red sub-pixel and a receiving opening of another sub-pixel adjacent to each other. For example, the second partition wall member PW2C′ and the first partition wall member PWIC′ may be disposed (e.g., interposed) between the (1-1)-th receiving opening RC1-1′ and the (2-1)-th receiving opening RC2-1′ adjacent to each other. For example, a second partition wall member PW2C′, a first partition wall member PW1C′, and another second partition wall member PW2C′ may be disposed (e.g., interposed) between the (1-1)-th receiving opening RC1-1′ and the (1-2)-th receiving opening RC2-1′ adjacent to each other.

In other embodiments, only the first partition wall member PWIC′ may be disposed (e.g., interposed) between a receiving opening of a green sub-pixel (or a receiving opening of a blue sub-pixel) and a receiving opening of a green sub-pixel (or a receiving opening of a blue sub-pixel adjacent) to each other. For example, only the first partition wall member PWIC′ may be disposed (e.g., interposed) between the (2-1)-th receiving opening RC2-1′ and the (3-1)-th receiving opening RC3-1′ adjacent to each other, between the (2-1)-th receiving opening RC2-1′ and the (2-2)-th receiving opening RC2-2′ adjacent to each other, and between the (3-1)-th receiving opening RC3-1′ and the (3-2)-th receiving opening RC3-2′ adjacent to each other.

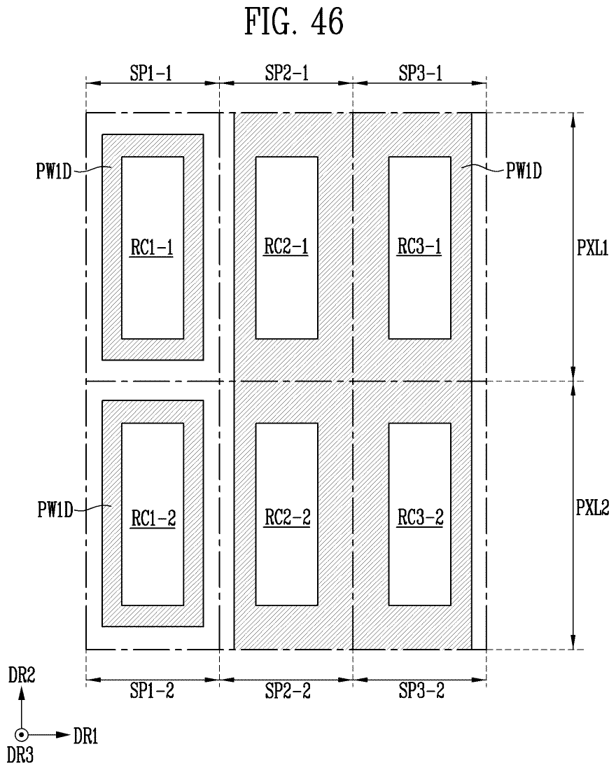

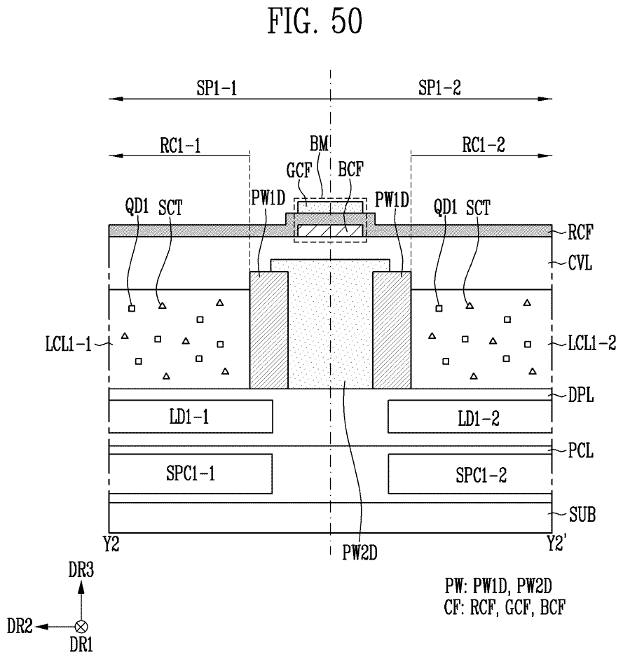

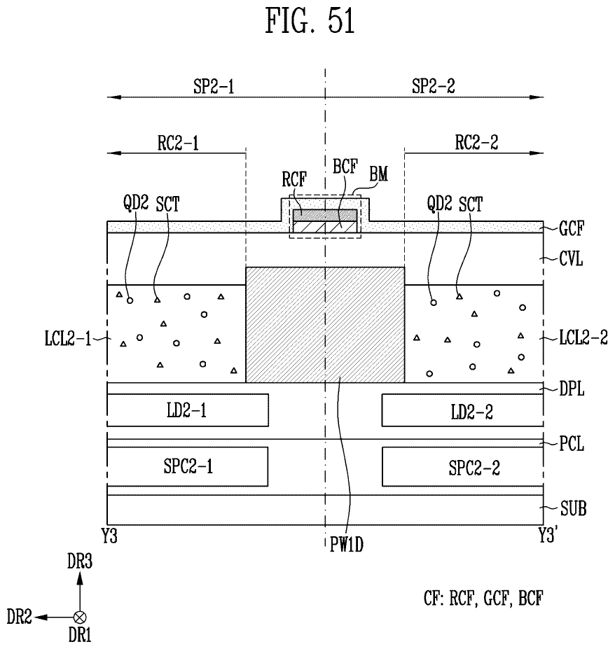

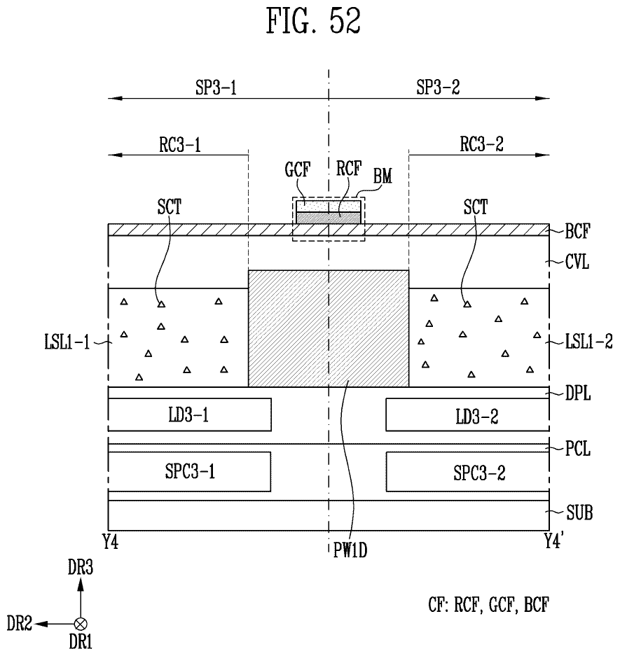

FIGS. 46 to 52 are schematic drawings illustrating an embodiment of the display device described with reference to FIGS. 4 to 13.

In describing FIGS. 46 to 52, a difference compared to the content described with reference to FIGS. 4 to 13 is described, and detailed description of the same or similar constituent elements is omitted.

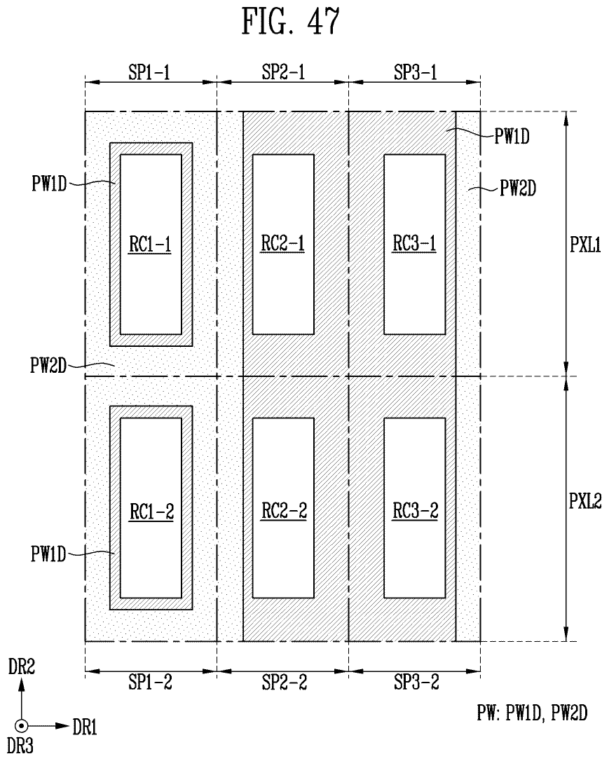

Referring to FIGS. 46 and 47, the partition wall member PW may include a first partition wall member PW1D and a second partition wall member PW2D.

The first partition wall member PW1D may be different from the first partition wall member PW1A at least in a planar shape. The first partition wall member PW1D may include a first portion including a (1-1)-th receiving opening (or a 1-1-th receiving opening) RC1-1, a second portion including a (1-2)-th receiving opening (or a 1-2-th receiving opening) RC1-2, and a third portion including a (2-1)-th receiving opening (or a 2-1-th receiving opening) RC2-1, a (2-2)-th receiving opening (or a 2-2-th receiving opening) RC2-2, a (3-1)-th receiving opening (or a 3-1-th receiving opening) RC3-1, and a (3-2)-th receiving opening (or a 3-2-th receiving opening) RC3-2. The first to third portions of the first partition wall member PW1D may be spaced apart from each other.

The second partition wall member PW2D may be different from the second partition wall member PW2A at least in a planar shape. The second partition wall member PW2D may fill a separation space between the first to third portions of the first partition wall member PW1D.

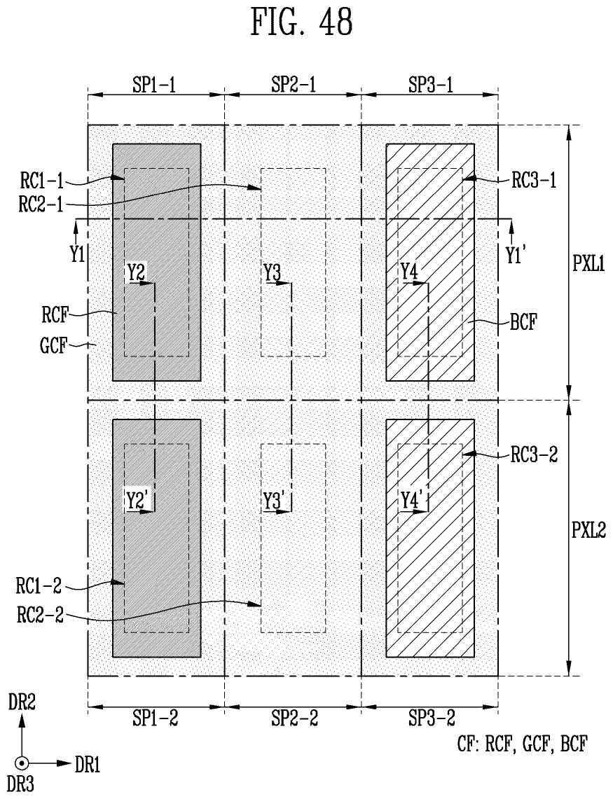

In FIG. 48, the color filter layer CF is shown. The color filter layer CF may be described similarly to that described with reference to FIGS. 6 to 9.

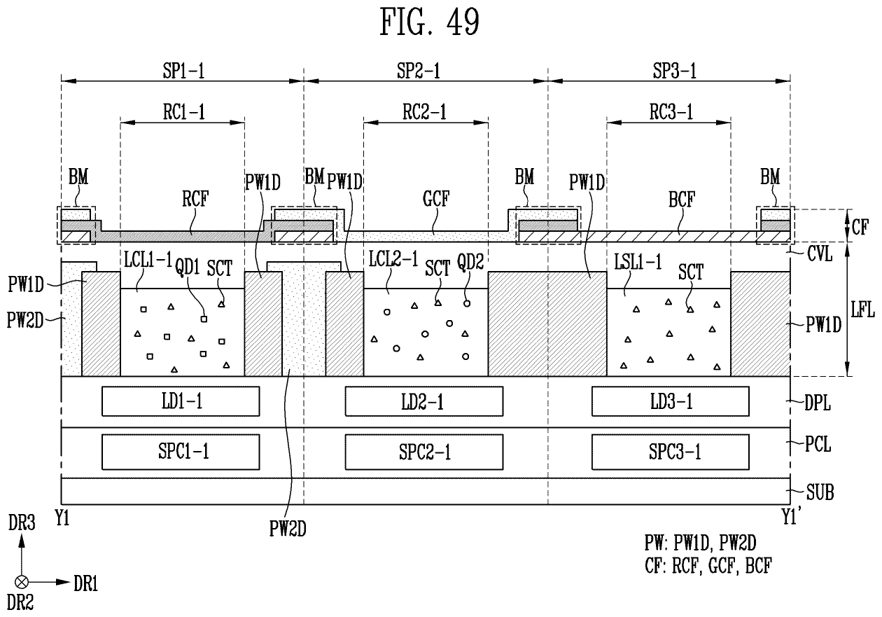

Referring to FIGS. 49 to 52, the first partition wall member PW1D and the second partition wall member PW2D may be disposed (e.g., interposed) between a receiving opening of a red sub-pixel and a receiving opening of another sub-pixel adjacent to each other. For example, a first partition wall member PW1D, a second partition wall member PW2D, and another first partition wall member PW1D may be disposed (e.g., interposed) between the (1-1)-th receiving opening RC1-1 and the (2-1)-th receiving opening RC2-1 adjacent to each other. For example, a first partition wall member PW1D, a second partition wall member PW2D, and another first partition wall member PW1D may be disposed (e.g., interposed) between the (1-1)-th receiving opening RC1-1 and the (1-2)-th receiving opening RC2-1 adjacent to each other.

In other embodiments, only the first partition wall member PW1D may be disposed (e.g., interposed) between a receiving opening of a green sub-pixel (or a receiving opening of a blue sub-pixel) and a receiving opening of a green sub-pixel (or a receiving opening of a blue sub-pixel) adjacent to each other. For example, only the first partition wall member PW1D may be disposed (e.g., interposed) between the (2-1)-th receiving opening RC2-1 and the (3-1)-th receiving opening RC3-1 adjacent to each other, between the (2-1)-th receiving opening RC2-1 and the (2-2)-th receiving opening RC2-2 adjacent to each other, and between the (3-1)-th receiving opening RC3-1 and the (3-2)-th receiving opening RC3-2 adjacent to each other.

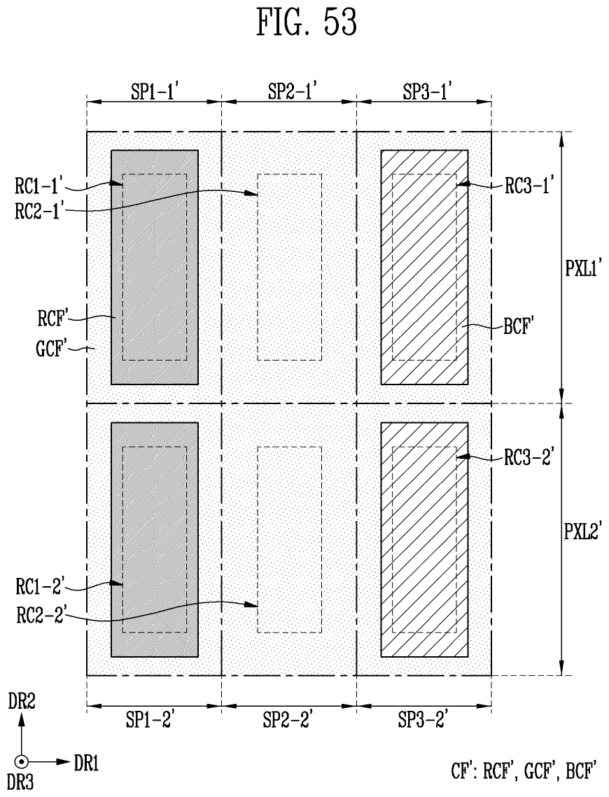

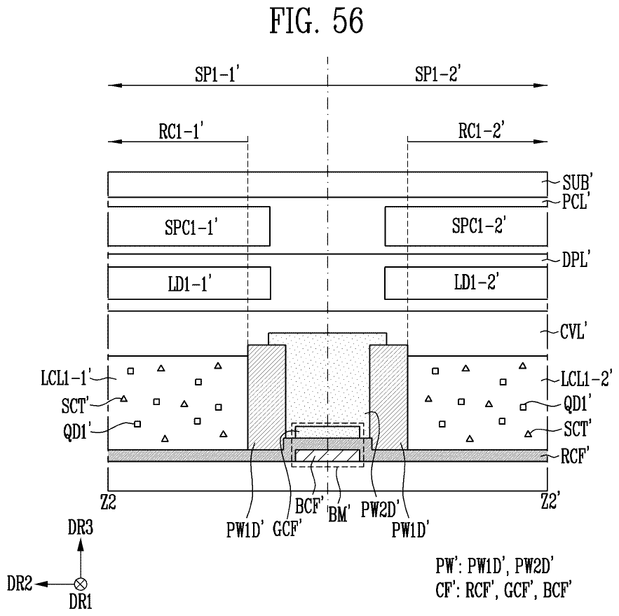

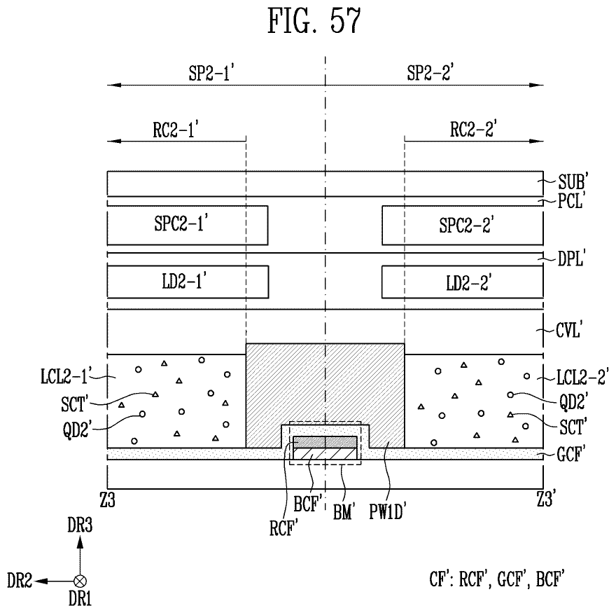

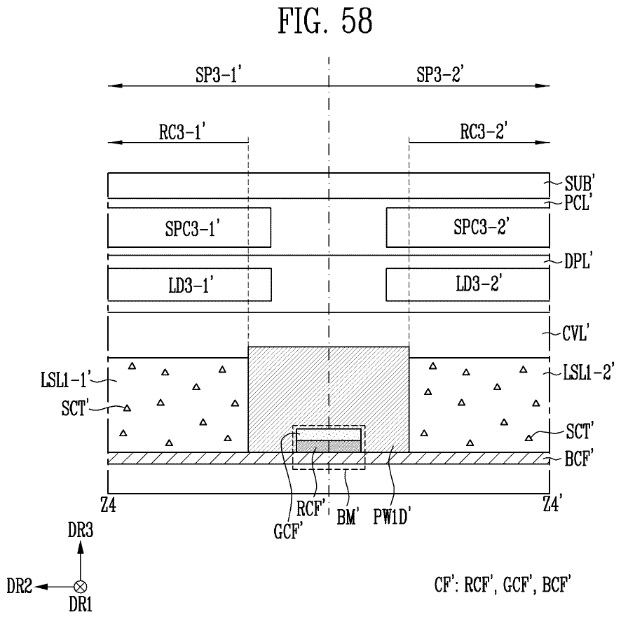

FIGS. 53 to 58 are schematic drawings illustrating an embodiment of the display device described with reference to FIGS. 14 to 19.

In describing FIGS. 53 to 58, a difference compared to the content described with reference to FIGS. 14 to 19 is described, and detailed description of the same or similar constituent elements is omitted.

In FIG. 53, the color filter layer CF′ is shown. The color filter layer CF′ may be described similarly to that described with reference to FIG. 14.

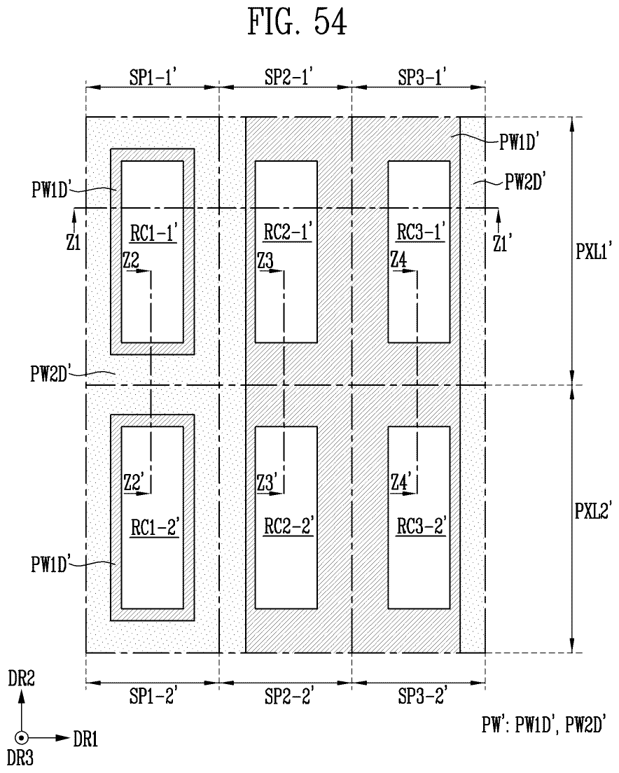

Referring to FIG. 54, the partition wall member PW′ may include a first partition wall member PW1D′ and a second partition wall member PW2D′.

The first partition wall member PW1D′ may be different from the first partition wall member PW1A′ (e.g., refer to FIG. 15) at least in a planar shape. The first partition wall member PW1D′ and the first partition wall member PW1D (e.g., refer to FIG. 46) may have the same planar shape.

The second partition wall member PW2D′ may be different from the second partition wall member PW2A′ (e.g., refer to FIG. 15) at least in a planar shape. The second partition wall member PW2D′ and the second partition wall member PW2D (e.g., refer to FIG. 47) may have the same planar shape.

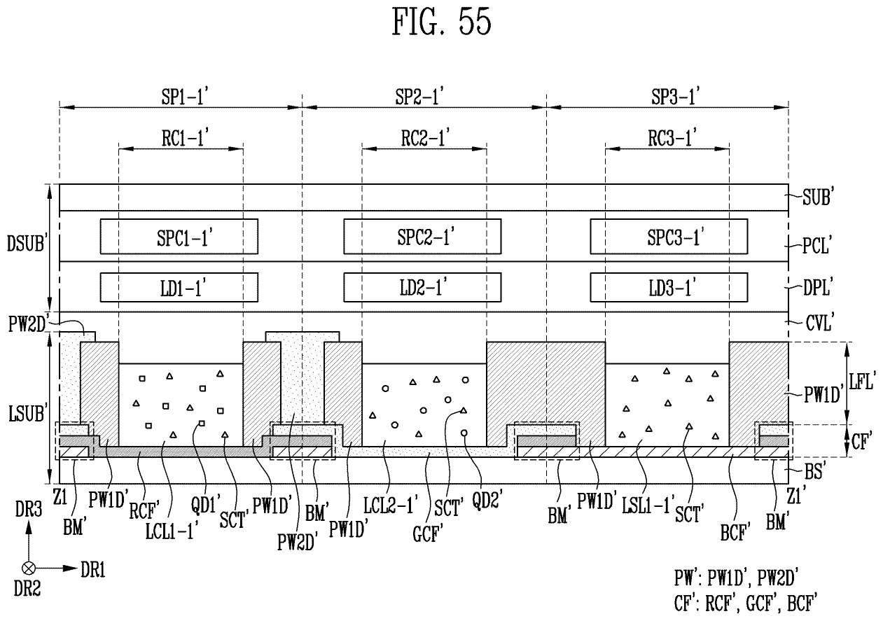

Referring to FIGS. 55 to 58, the first partition wall member PW1D′ and the second partition wall member PW2D′ may be disposed (e.g., interposed) between a receiving opening of a red sub-pixel and a receiving opening of another sub-pixel adjacent to each other. For example, a first partition wall member PW1D′, a second partition wall member PW2D′, and another first partition wall member PW1D′ may be disposed (e.g., interposed) between the (1-1)-th receiving opening RC1-1′ and the (2-1)-th receiving opening RC2-1′ adjacent to each other. For example, a first partition wall member PW1D′, a second partition wall member PW2D′, and another first partition wall member PW1D′ may be disposed (e.g., interposed) between the (1-1)-th receiving opening RC1-1′ and the (1-2)-th receiving opening RC2-1′ adjacent to each other.

In other embodiments, only the first partition wall member PW1D′ may be disposed (e.g., interposed) between a receiving opening of a green sub-pixel (or a receiving opening of a blue sub-pixel) and a receiving opening of a green sub-pixel (or a receiving opening of a blue sub-pixel) adjacent to each other. For example, only the first partition wall member PW1D′ may be disposed (e.g., interposed) between the (2-1)-th receiving opening RC2-1′ and the (3-1)-th receiving opening RC3-1′ adjacent to each other, between the (2-1)-th receiving opening RC2-1′ and the (2-2)-th receiving opening RC2-2′ adjacent to each other, and between the (3-1)-th receiving opening RC3-1′ and the (3-2)-th receiving opening RC3-2′ adjacent to each other.

A display device according to an embodiment is applicable to various types of electronic devices. In an embodiment, an electronic device includes the above-described display device and may further include other modules or devices having additional functions in addition to the display device.

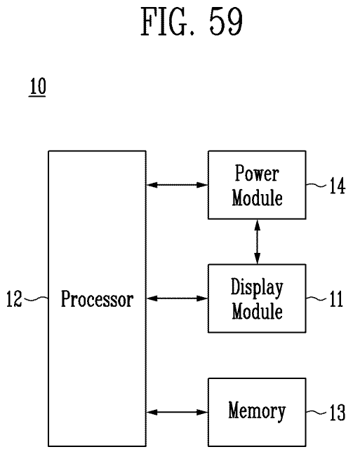

FIG. 59 is a block diagram of an electronic device according to an embodiment.

Referring to FIG. 59, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

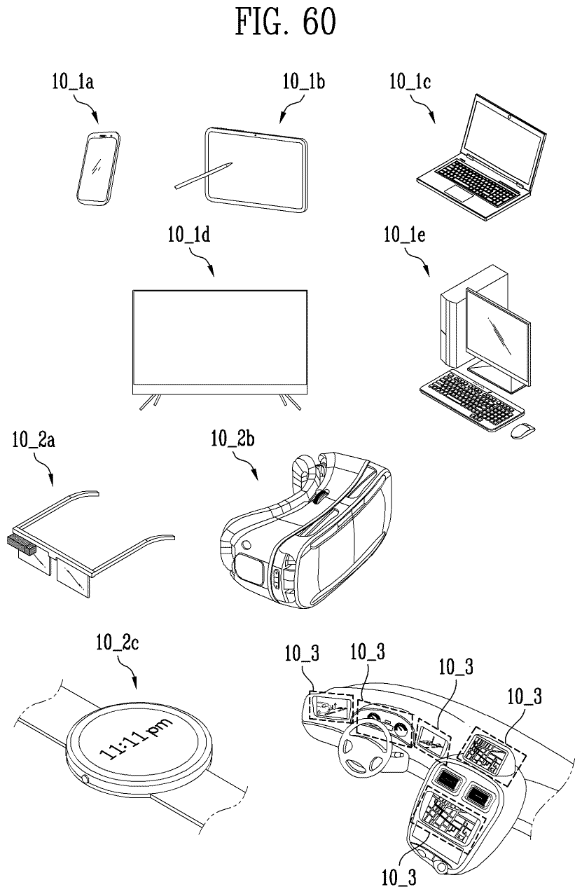

FIG. 60 shows schematic views of various embodiments of an electronic device.

Referring to FIG. 60, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light emitting element layer including:
first light emitting elements;
second light emitting elements; and
third light emitting elements;
a partition wall member disposed on the light emitting element layer, and including:
first receiving openings overlapping the first light emitting elements in a plan view;
second receiving openings overlapping the second light emitting elements in a plan view; and
third receiving openings overlapping the third light emitting elements in a plan view;
first color conversion layers disposed in the first receiving openings;
second color conversion layers disposed in the second receiving openings;
scattering layers disposed in the third receiving openings;
a cover layer covering the partition wall member, the first color conversion layers, the second color conversion layers, and the scattering layers; and
a color filter layer disposed on the cover layer, and including:
a first color filter layer including a first color filter material;
a second color filter layer including a second color filter material; and
a third color filter layer including a third color filter material,
wherein the partition wall member includes:
a first partition wall member including the first color filter material; and
a second partition wall member including the second color filter material.

2. The display device according to claim 1, wherein in a cross-section, the first partition wall member and the second partition wall member are disposed between a first receiving opening of the first receiving openings and a second receiving opening of the second receiving openings adjacent to each other.

3. The display device according to claim 1, wherein in a cross-section, the first partition wall member and the second partition wall member are disposed between adjacent ones of the first receiving openings.

4. The display device according to claim 1, wherein in a cross-section, the first partition wall member and the second partition wall member are disposed between a first receiving opening of the first receiving openings and a third receiving opening of the third receiving openings adjacent to each other.

5. The display device according to claim 1, wherein in a cross-section, at least the first partition wall member is disposed between a second receiving opening of the second receiving openings and a third receiving opening of the third receiving openings adjacent to each other.

6. The display device according to claim 1, wherein in a cross-section, at least the first partition wall member is disposed between adjacent ones of the second receiving openings.

7. The display device according to claim 1, wherein in a cross-section, at least the first partition wall member is disposed between adjacent ones of the third receiving openings.

8. The display device according to claim 1, wherein the color filter layer defines a light blocking member having a triple-layer structure in which the first color filter layer, the second color filter layer, and the third color filter layer are stacked each other.

9. The display device according to claim 8, wherein in a cross-section, a width of the light blocking member is less than a width of the partition wall member.

10. The display device according to claim 1, wherein
each of the first color conversion layers includes first color conversion particles,
each of the second color conversion layers includes second color conversion particles, and
each of the scattering layers includes scattering particles.

11. The display device according to claim 1, wherein each of the first partition wall member and the second partition wall member further includes a liquid repellent material.

12. The display device according to claim 1, wherein
the first color filter material selectively transmits light of red color,
the second color filter material selectively transmits light of green color, and
the third color filter material selectively transmits light of blue color.

13. A display device comprising:
a color conversion substrate;
a display substrate facing the color conversion substrate, and including a plurality of light emitting elements; and
a filling layer disposed between the color conversion substrate and the display substrate,
wherein the color conversion substrate comprises:
a color filter layer including:
a first color filter layer including a first color filter material;
a second color filter layer including a second color filter material; and
a third color filter layer including a third color filter material;
a partition wall member disposed on the color filter layer, and including:
first receiving openings overlapping the first color filter layer in a plan view;
second receiving openings overlapping the second color filter layer in a plan view; and
third receiving openings overlapping the third color filter layer in a plan view;
first color conversion layers disposed in the first receiving openings;
second color conversion layers disposed in the second receiving openings; and
scattering layers disposed in the third receiving openings, and
the partition wall member includes:
a first partition wall member including the first color filter material; and
a second partition wall member including the second color filter material.

14. The display device according to claim 13, wherein the partition wall member is directly disposed on the color filter layer.

15. The display device according to claim 13, wherein
the first receiving openings do not overlap the second color filter layer and the third color filter layer in a plan view,
the second receiving openings do not overlap the first color filter layer and the third color filter layer in a plan view, and
the third receiving openings do not overlap the first color filter layer and the second color filter layer in a plan view.

16. The display device according to claim 13, wherein the color filter layer defines a light blocking member having a triple-layer structure in which the first color filter layer, the second color filter layer, and the third color filter layer are stacked each other.

17. The display device according to claim 16, wherein in a cross-section, a width of the light blocking member is less than a width of the partition wall member.

18. The display device according to claim 13, wherein each of the first color conversion layers includes first color conversion particles,
each of the second color conversion layers includes second color conversion particles, and
each of the scattering layers includes scattering particles.

19. The display device according to claim 13, wherein each of the first partition wall member and the second partition wall member further includes a liquid repellent material.

20. The display device according to claim 13, wherein
the first color filter material selectively transmits light of red color,
the second color filter material selectively transmits light of green color, and
the third color filter material selectively transmits light of blue color.

21. An electronic device comprising:
a display device; and
a power supply which provides power to the display device,
wherein the display device includes:
a light emitting element layer including:
first light emitting elements;
second light emitting elements; and
third light emitting elements;
a partition wall member disposed on the light emitting element layer, and including:
first receiving openings overlapping the first light emitting elements in a plan view;
second receiving openings overlapping the second light emitting elements in a plan view; and
third receiving openings overlapping the third light emitting elements in a plan view;
first color conversion layers disposed in the first receiving openings;
second color conversion layers disposed in the second receiving openings;
scattering layers disposed in the third receiving openings;
a cover layer covering the partition wall member, the first color conversion layers, the second color conversion layers, and the scattering layers; and
a color filter layer disposed on the cover layer, and including:
a first color filter layer including a first color filter material;
a second color filter layer including a second color filter material; and
a third color filter layer including a third color filter material,
wherein the partition wall member includes:
a first partition wall member including the first color filter material; and
a second partition wall member including the second color filter material.

22. The electronic device of claim 21, wherein the electronic device is at least one of a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a tablet computer, a phablet, a personal digital assistant (PDA), a wearable device, a laptop computer, a digital camera, a camcorder, a viewfinder, a micro display, a three-dimensional (3D) display, a vehicle, a video wall with multiple displays tiled together, a theater screen, a stadium screen, a phototherapy device, and a signboard.
